(19) United States
(12) Patent Application Publication
(10) Pub. No.: US 2026/0121586 A1
(43) Pub. Date: Apr. 30, 2026

(54) ARCHITECTURE FOR COMBINING DUAL BIAS DIGITAL POWER AMPLIFIER (PA) CELLS

(71) Applicant: Intel Corporation, Santa Clara, CA (US)

(72) Inventors: Yuri Rozenfeld, Haifa (IL); Ofir Degani, Nes-Ammin (IL); Yishai Eilat, Alonei Aba (IL)

(21) Appl. No.: 19/430,662

(22) Filed: Dec. 23, 2025

(51) Int. Cl. H03F 1/02; H03F 1/56; H03F 3/213

(52) U.S. Cl. CPC H03F 1/0244; H03F 1/56; H03F 3/213; H03F 2200/174; H03F 2200/279; H03F 2200/451

(57) ABSTRACT

A digital power amplifier (DPA) architecture addresses power efficiency limitations in shared PA designs supporting multiple communication protocols with differing transmission power requirements. The DPA comprises PA cell arrays, with each cell including both low voltage (LV) and high voltage (HV) domain PA cells that are separately activated. For low power transmissions, LV domain cells operate while HV domain cells are placed into a high-impedance state to minimize loading and improve efficiency. For high power transmissions, both LV and HV domain cells operate to achieve desired transmit power. The architecture includes a unified combiner coupling both voltage domains, domain-specific output stages optimized for respective voltage levels, and a differential level shifter providing amplitude-preserving voltage conversion for HV domain control. This dual bias topology enables significant power efficiency improvements across wide transmission power ranges compared to conventional single-bias or Class G DPA architectures.

### BACKGROUND

Recently, there has been a shift towards digital transmitter (DTX) architectures due to their compact die area, scalability in advance CMOS processes, and improved power efficiency of their switching digital power amplifiers (DPAs). Recently, high voltage switched capacitor DPA topologies have been proposed based on triple (or even higher numbers of devices) stack floating gate feedback. Such topologies provide higher transmit power levels, improved memory effects due to lower current consumption, and can withstand reliability considerations. However, one of the main limitations of high voltage DPAs is power efficiency at low power modes (i.e. when implementing high back off levels). That is, for shared DPA architectures that serve both higher power and lower power communication protocols (e.g. Wi-Fi and Bluetooth), this limitation becomes critical for scenarios in which one communication protocol has a significantly lower operating power level. Thus, current DPA architectures that implement a shared design to support two or more communication protocols with differing transmission power levels have significant drawbacks.

### BRIEF DESCRIPTION OF THE DRAWINGS/FIGURES

The accompanying drawings, which are incorporated herein and form a part of the specification, illustrate the aspects of the present disclosure and, together with the description, further serve to explain the principles of the aspects and to enable a person skilled in the pertinent art to make and use the aspects.

FIG. 1 illustrates a block diagram of a conventional digital power amplifier (DPA);

FIG. 2 illustrates a block diagram of a dual bias DPA, in accordance with the disclosure;

FIG. 3A illustrates a DPA level shifting circuit, in accordance with the disclosure;

FIG. 3B illustrates a floating gate circuit for providing the bias voltages;

FIG. 4 illustrates a high voltage (HV) output driving stage, in accordance with the disclosure;

FIG. 5 illustrates a low voltage (LV) output driving stage, in accordance with the disclosure;

FIG. 6 illustrates a layout view illustration of DPA arrays connected to a combiner of a dual bias DPA including a combiner structure, in accordance with the disclosure;

FIG. 7A illustrates a detailed layout view of the primary branches of the DPA combiner structure, in accordance with the disclosure;

FIG. 7B illustrates a detailed layout view of the secondary branch of the DPA combiner structure, in accordance with the disclosure;

FIG. 8 illustrates a graph of power efficiency (PE) vs transmission output power (Pout) that compares the performance between a conventional, Class G, and dual bias topologies, in accordance with the disclosure;

FIG. 9 illustrates a graph of output amplitude (Amp) vs code that compares the performance between a conventional, Class G, and dual bias topologies, in accordance with the disclosure;

FIG. 10 illustrates an apparatus, in accordance with the disclosure; and

FIG. 11 illustrates a process flow, in accordance with the disclosure.

The exemplary aspects of the present disclosure will be described with reference to the accompanying drawings. The drawing in which an element first appears is typically indicated by the leftmost digit(s) in the corresponding reference number.

### DETAILED DESCRIPTION

In the following description, numerous specific details are set forth in order to provide a thorough understanding of the aspects of the present disclosure. However, it will be apparent to those skilled in the art that the aspects, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

Again, current shared DPA architectures that support two or more communication protocols with differing transmission power levels have significant drawbacks. For instance, conventional architectures include the use of two separate DPAs, with each DPA being connected to a dedicated matching network. Typically, one DPA serves a higher-power protocol such as Wi-Fi, whereas the other DPA serves a lower power protocol such as Bluetooth. However, implementing two separate DPAs is a silicon area compromise, and results in increased product cost. In addition, such dual DPA architectures fail to address the low efficiency problem for lower transmit power protocols.

Moreover, conventional DPA solutions include single bias DPAs, although such designs are inefficient for transmission at lower power levels. Thus, dual mode DPAs have been introduced that, in a predefined mode, operate from an HV supply (for higher power transmissions) and a LV supply (for lower power transmissions). Also, class G DPAs are often used, which implement a dynamically variable supply that facilitates toggling between two predefined values, i.e. a HV supply (for high power transmissions) and a LV supply (for low power transmissions). However, dual mode DPAs and Class G DPAs architectures comprise PA cells, with the same PA cells operating both from an HV and an LV supply, making them less efficient and significantly complex. Additionally, dual mode DPAs and Class G DPAs cannot be optimized simultaneously for large and small output signals, and thus a compromise must be found for the overall transmission power output range.

The disclosure is directed to a DPA architecture that addresses these issues by combining low voltage (LV) and high voltage (HV) PA cells into a shared “mixed power domain” array. Thus, the “mixed” power supply domain DPA includes a number of power amplifier (PA) cell arrays, with each PA array containing both LV domain cells and HV domain cells. In this configuration, each domain may be advantageously coupled to its own dedicated and optimized load. As a result, for low power transmissions, only LV domain cells are actively operating while the HV domain cells are placed into a high impedance mode to minimize loading and improve efficiency for such lower power transmissions. As the output power increases, the HV cells may be selectively activated and their contribution summed with the LV domain cells to reach the desired higher transmit power levels. Thus, the DPA architecture as discussed herein may advantageously be implemented to support two separate communication protocols that transmit in accordance with different power levels (such as Bluetooth and Wi-Fi) or, alternatively, a single communication protocol that may achieve a wide range of transmit power via the combination of the LV and HV domain cells.

That is, the DPA architecture as discussed herein may implement dedicated optimal drivers for separate high power and low power transmissions, and also provides a dedicated optimal load for each of the HV and LV PA cells for such transmissions. The DPA architecture provides a significant area savings, as there is no need to maintain two separate sets of independently controlled LV and HV PA cell arrays, as is required for conventional mixed power domain DPA architectures. Instead, the DPA architecture as discussed herein may implement simple DTX logic and reduce complexity and design effort compared to conventional DPA solutions. The DPA architecture as discussed herein also enables the contributions from the LV and HV PA cells to be summed via a unified combiner, which further reduces chip area. Thus, and as discussed in further detail herein, this DPA architecture is highly efficient and provides an extremely compact solution.

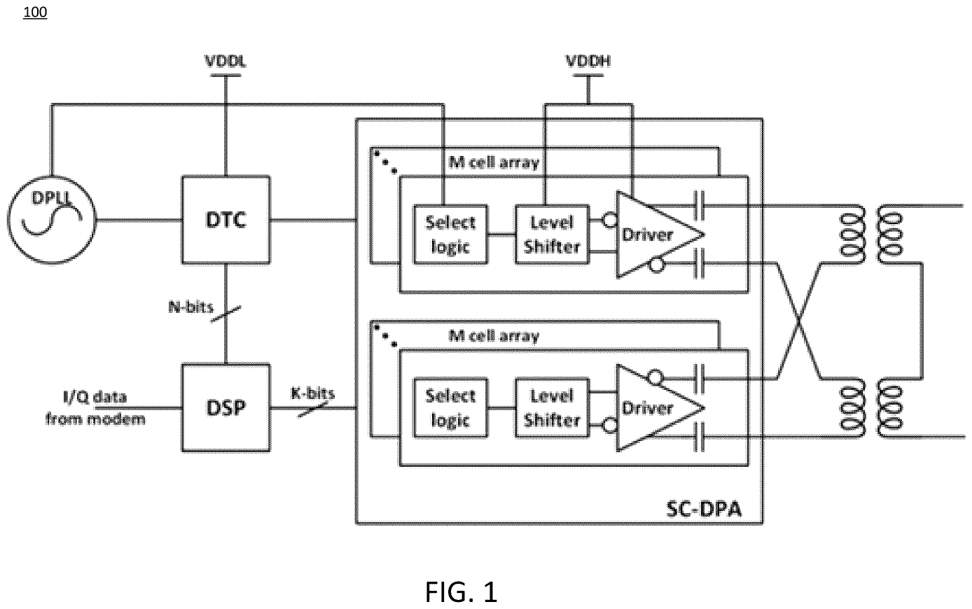

FIG. 1 illustrates a block diagram of a conventional digital power amplifier (DPA). The conventional DPA 100 as shown in FIG. 1 is implemented as a polar digital transmitter for ease of explanation and comparison with the dual bias DPA as discussed in further detail herein. The DPA as shown in FIG. 1 is based upon a radio frequency (RF) digital-to-analog conversion (DAC) (RF-DAC) design in which a switched capacitor DAC (SC-DAC) topology is implemented for the power driving stage to the load. The number of PA cells in the array may vary based upon the particular power requirements, application, communication protocol, etc., with typical numbers of cells being 64, 128, 256, etc. In any event, each of the PA cells within the array may be digitally-controlled and output a signal that is coupled to a suitable DAC component, which then combines and converts each of the digital output signals to create an analog output signal for transmission via an appropriately coupled antenna.

Such a DAC component may include known implementations of radio-frequency digital-to-analog converters (RF-DACs) that function to both sum the digital output signals and convert the summed signals to an analog output signal. The output signal thus has an amplitude that is a function of the number of cells in the array that are “on” or actively contributing to the desired analog output. In this way, SC-DPAs function to selectively combine digital signals to achieve a desired transmit power level via the selective combination of appropriate digital signals, thereby accommodating various modulation schemes.

To do so, the DSP receives in-phase and quadrature (I/Q) digital data streams (represented as I/Q or rectangular coordinates). As shown in FIG. 1, the DSP then converts this I/Q data into polar coordinates, which includes amplitude and phase data. The DSP thus receives the I/Q data from the modem and generates the control signals that are provided to the DTC in the form of a digital code of N bits, which is used by the DTC to modulate the phase of a local oscillator (LO) signal provided by the DPLL. This modulated LO signal is then input to all cells in DPA. The DTC thus ensures that the phase and amplitude signals are extracted at the correct time instants (i.e., time-aligned with phase modulated output) from the in-phase and quadrature-phase signals fed into the DSP. The DSP also generates, from the I/Q data received via the modem, control data of K bits, which may be identified with a digital word that is used to drive the select logic included in each of the M cell arrays. The SC-DAC topology uses an array of switches and capacitors to convert a digital signal into an analog radio frequency (RF) signal for transmission, with the switches controlling the charging and discharging of the resonant capacitors at the output of the drivers as shown in FIG. 1 to facilitate this conversion process. The switching of the capacitors in this manner creates a time-varying output voltage in accordance with a desired transmission power level. Thus, the amplitude at the output of the DPA is a function of number of switched cells, which is controlled by the K-bit control data.

That is, control of the output amplitude and power in the conventional DPA 100 is achieved through digital control signals that determine the number of active cells in the M cell arrays. The select logic processes the K-bit control word to determine which cells should be activated or deactivated, and the level shifters convert these control signals to the appropriate voltage levels for driving the output stages. The drivers are thus activated to drive the selected PA cells accordingly. By controlling the number of on/off cells in the array, the conventional DPA adjusts its transmit power level, but faces efficiency challenges across varying power levels given that each cell array is identical and operates at the same voltage levels. Thus, when operating at lower power transmission levels, cells may remain unused, resulting in suboptimal power efficiency. This limitation becomes particularly pronounced in applications requiring operation across multiple communication protocols with significantly different power requirements, such as systems that must support both low-power Bluetooth transmissions and higher-power Wi-Fi transmissions.

Thus, the signals output by each cell within the array vary over time as a function of the time-varying characteristics of the analog signal to be transmitted. The DPA architectures as discussed herein are described with respect to a single DPA driver cell in such a configuration of an array of DPA cells. The details and operation of the SC-DPA in accordance with such a cell array architecture is generally known, and thus additional details regarding its operation are omitted for purposes of brevity.

### I. A Dual Bias DPA Architecture

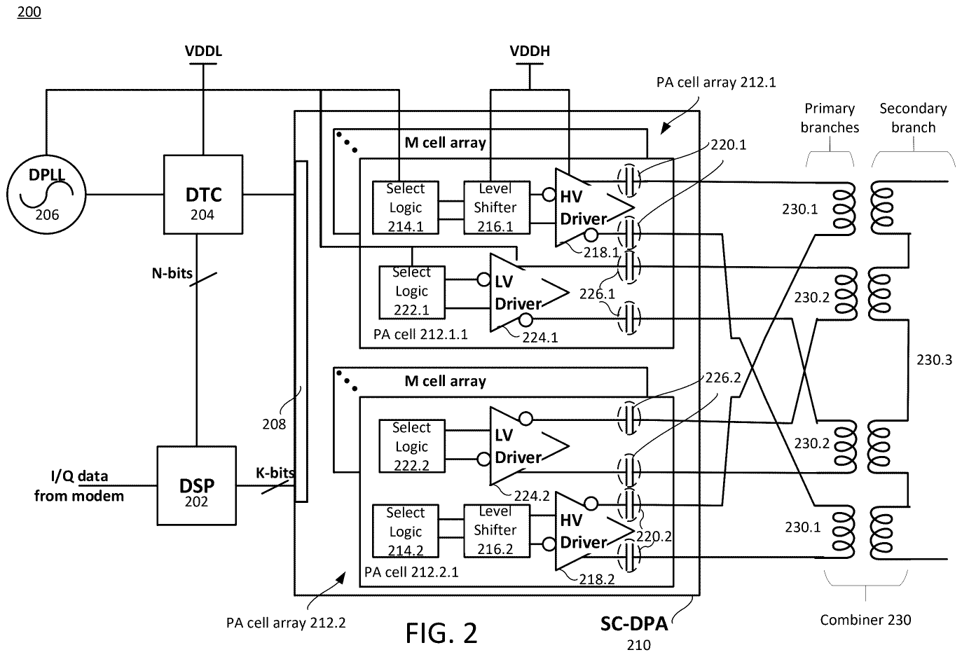

FIG. 2 illustrates a block diagram of a dual bias DPA, in accordance with the disclosure. The DPA 200 as shown in FIG. 2 includes components that are analogous to those described with respect to the conventional DPA 100 as shown in FIG. 1. For instance, the DPA 200 also includes a DSP 202 (also referred to herein as processing circuitry or control circuitry), a DTC 204, and a DPLL 206 that may operate in a similar or identical manner as the same components as discussed with respect to the conventional DPA 100. Thus, the DSP 202, the DTC 204, and the DPLL 206 may be implemented in accordance with any suitable components, including known components, and may be configured to operate in accordance with any suitable manner to achieve their respective functions as discussed herein.

The DPA architecture 200 may form part of an overall DPA design that includes a switched-capacitor digital power amplifier (SC-DPA) 210, as shown in FIG. 2. As further discussed herein, as the DPA 210 may implement both LV and HV domain cells, which may utilize two different voltage levels, the DPA 210 may be referred to herein as a dual bias DPA or, alternatively, as a hybrid DPA. The DPA architecture 200 may be implemented in accordance with any suitable DPA that implements a switched-capacitor topology as discussed in further detail herein. For instance, the DPA architecture 200 may be implemented as part of a Class-G switched-capacitor RF power amplifier design. Moreover, the DPA architecture 200 is described in accordance with a polar modulation scheme and a differential signal implementation. However, these implementations are illustrative and not intended to be limiting, and the DPA architecture 200 as discussed herein may be modified to work in accordance with any suitable type of modulation scheme, wireless communication protocols, single-ended or differential signaling, etc.

The SC-DPA 210, which may alternatively be referred to herein simply as DPA 210, may include a data interface 208 as shown. The data interface 208 may be configured to receive the control data via the DSP 202, which again may comprise digital data such as a K-bit control word, as well as the DTC data output via the DTC 204 and any other suitable signals that are implemented by the DPA 210 as discussed herein (such as LO signals provided via the DPLL). Again, the DTC data output via the DTC 204 may be provided to downstream circuitry for phase modulation timing control (not shown), which ensures that the phase modulation and amplitude modulation are properly time-aligned. Thus, the data interface 208 may include any suitable number of components to facilitate the K-bit control data generated via the DSP 202, as well as any other suitable data utilized by the DPA 210, being received and coupled to any suitable components of the DPA 210, as further discussed herein. Thus, the data interface 208 may comprise one or more pins, terminals, buses, wires, couplings, buffers, etc.

Therefore, the DPA architecture 200 also receives I/Q data from a modem, which is processed through the DSP 202 to generate polar coordinates including amplitude and phase data. The phase data is provided to the DTC 204, which translates the digital phase data into precise time variations of the carrier signal in accordance with the DPLL signal. The DSP 202 outputs the K-bit control data, which again may include a K-bit digital word that is provided to the select logic within the PA cell arrays, as discussed in further detail herein. Of course, although the DPA architecture 200 is discussed herein with respect to the use of a polar transmitter architecture this is a non-limiting and illustrative scenario, and the DPA architecture 200 may implement any suitable type of transmitter architecture, such as a rectangular architecture for instance.

However, unlike the conventional DPA architecture of FIG. 1, the DPA architecture 200 may implement a mixed power domain per PA cell. That is, and with continued reference to FIG. 2, the DPA 210 may include any suitable number of digital PA cell arrays 212, with two PA cell arrays 212.1, 212.2 being shown for ease of explanation and not by way of limitation. Thus, the DPA 210 may include a single PA cell array 212 or any suitable number of PA cell arrays greater than the two as shown.

Moreover, each PA cell array 212 may comprise any suitable number of PA cells, with a portion of the PA cells operating within a high voltage domain and the other portion of the PA cells operating within a low voltage domain, as discussed in further detail below. FIG. 2 illustrates additional details with respect to the two PA cells 212.1.1 and 212.2.1 as shown, although it is noted that each PA cell within each PA cell array 212.1, 212.2 may likewise include similar or identical components. Thus, each of the PA cells as shown in FIG. 2 may operate as a mixed power mode PA cell, with each PA cell 212.1.1, 212.2.1 including both a low voltage (LV) domain PA cell and a high voltage (HV) domain PA cell (also referred to herein simply as LV PA cells and HV PA cells, or simply LV cells and HV cells, respectively), each being separately activated based upon the K-bit control data and accompanying select logic 214, 222 as discussed in further detail herein.

The HV PA cell of each PA cell 212.1.1, 212.2.1 may comprise select logic 214.1, 214.2, a level shifter 216.1, 216.2, and an HV driver 218.1, 218.2, respectively, as shown. The HV drivers 218.1, 218.2, may comprise a respective HV output stage of each HV PA cell in this manner, and thus each HV driver 218.1, 218.2 may be coupled to a set of HV resonance capacitors 220.1, 220.2. The resonance capacitors 220.1, 220.2 may have a particular size and/or value that is implemented based on the high voltage operating characteristics and/or transmit power of the coupled HV PA cells. Thus, each of the HV PA cells may be configured to generate, based on the control data provided by the DSP 202, a respective HV output signal that is coupled to the resonance capacitors 220.1, 220.2. These output signals may then be transmitted as part of a wireless signal after being combined via the coupled combiner 230, as further discussed herein.

Furthermore, the LV PA cell of each PA cell 212.1.1, 212.2.1 may comprise select logic 222.1, 222.2 that is coupled to a respective LV driver 224.1, 224.2 as shown. The LV drivers 224.1, 224.2 may comprise a respective LV output stage of each LV PA cell in this manner. The LV drivers 224.1, 224.2 may be coupled to a set of LV resonance capacitors 226.1, 226.2 that may also have a particular size and/or value that is implemented based on the low voltage operating characteristics and/or transmit power of the LV PA cells. Thus, the LV PA cells may be configured to generate, based on the control data provided by the DSP 202, a respective LV output signal that is coupled to the resonance capacitors 226.1, 226.2. These output signals may then be transmitted as part of a wireless signal after being combined via the coupled combiner 230, as further discussed herein.

It is further noted that the PA cells 212.1.1, 212.2.1 are shown in FIG. 2 as including the same number of HV and LV cells, with one of each type. However, the DPA 210 is not limited to this particular ratio of HV and LV cells per PA cells 212.1.1, 212.2.1, and each of the PA cells 212.1.1, 212.1.2, etc., of each PA cell array 212.1, 212.2 may include any suitable number of HV and LV cells, which may present in the same number or different numbers (not shown) per PA cell 212.1.1, 212.2.1. Furthermore, the PA cell arrays 212.1, 212.2 are shown in FIG. 2 as each comprising the same number “M” of PA cells, although this is also an illustrative scenario and is not intended to be limiting. Thus, not only may the DPA 210 include any suitable number of PA cell arrays 212.1, 212.2, etc., but each of the PA cell arrays may also include any suitable number of PA cells, which may be the same or different from one another in number and/or the proportion of HV and LV PA cells included therein.

The use of separate HV and LV cells per PA cell of each PA cell array enables the control data, which again is provided by the K-bit control word generated via the DSP 202, to facilitate a separate activation of the LV PA cells and the HV PA cells of the PA cell arrays 212.1, 212.2. In doing so, the DPA 210 enables a selective adjustment of the transmit power level in accordance with the desired power level implemented by the current communication protocol. For instance, the topology of the DPA 210 enables each of the HV cells of the PA cell arrays 212.1, 212.2 to be placed into a high-impedance state and thus not load the LV PA cells for lower-power transmissions. These lower power transmissions may be identified, in various scenarios, with a threshold or maximum transmit power level implemented in accordance with a particular communication protocol, such as Bluetooth.

In other words, the control data provided by the DSP 202 facilitates, for a transmit power level in accordance with a lower transmit power communication protocol, the LV domain PA cells generating a respective LV output signal (e.g. via the LV drivers 224.1, 224.2) while the HV domain PA cells are placed into a high-impedance state. Then, when a higher output transmit power level is needed, such as a threshold or maximum transmit power level implemented in accordance with a different communication protocol such as Wi-Fi, the control data provided by the DSP 202 may activate additional HV PA cells of the various PA cell arrays 212.1, 212.2, etc., to accommodate these higher transmission power levels. That is, when higher transmit power is utilized, the LV domain PA cells may generate their respective LV output signals while the HV domain PA cells generate their respective HV output signals, each being combined to achieve a wireless signal transmission in accordance with the higher power levels.

To this end, it is noted that illustrative scenarios are described herein with respect to the lower transmit power communication protocol being Bluetooth and the higher transmit power communication protocol being Wi-Fi. Bluetooth protocols implemented may include any suitable variation and/or specification of the Bluetooth protocols, such as classic Bluetooth or Bluetooth low energy (BLE), with the Bluetooth protocol being defined in accordance with the IEEE 802.15.1 specification and/or those defined in accordance with the Bluetooth Core Specification, with Version 6.1 published on May 2025 by the Bluetooth Special Interest Group (SIG) being the most recent as of the time of this writing.

Wi-Fi protocols implemented may include any suitable variation and/or specification of IEEE 802.11, which may be defined in accordance with the IEEE 802.11 specifications and/or standards, with the IEEE 802.11be-2024 standard (also known as Wi-Fi 7), published on Jul. 22, 2025, being the most recent as of the time of this writing. Other Wi-Fi protocols that may be implemented may include any suitable standards of the 802.11 protocol such as 802.11a, 802.11b, 802.11g, 802.11n, 802.11p, 802.11-12, 802.11ac, 802.11ad, 802.11ah, 802.11ax, 802.11ay, etc.

However, these communication protocols are again non-limiting and illustrative, and the DPA architecture 200 may facilitate data transmissions via the DPA 210 in accordance with any suitable number and/or type of communication protocols. Additional illustrative and non-liming scenarios of communication protocols, which may be implemented for low power and/or high power transmissions as discussed herein, may include Short Range mobile radio communication standard such as Zigbee, Medium or Wide Range mobile radio communication standard such as Universal Mobile Telecommunications System (UMTS), Long Term Evolution (LTE), or any suitable mobile radio communication standard in accordance with a corresponding (3rd Generation Partnership Project) 3GPP standard.

Furthermore, and as noted above, the DPA architecture 200 is primarily discussed herein as being implemented to support two separate communication protocols that transmit in accordance with different power levels. However, this is also illustrative and not limiting, as the DPA architecture 200 may alternatively operate in accordance with a single communication protocol. Doing so may advantageously allow for the efficient transmission over a wide range of power levels by utilizing the combination of the LV and HV domain cells as discussed herein.

Additionally, the use of separate LV domain and HV domain cells enables the use of different dedicated capacitors 220.1, 220.2, and 226.1, 226.2, which may have different sizes and/or values among the different LV PA cells and the HV PA cells. That is, the capacitors 220.1, 220.2 may have one size and/or value (which may be the same as one another), whereas the capacitors 226.1, 226.2 may have a different size and/or value (but may be the same as one another) compared to the capacitors 220.1, 220.2. The capacitors 220.1, 220.2, 226.1, 226.2 may comprise resonance capacitors, as noted above, as each of the different capacitors 220.1, 220.2, 226.1, 226.2 may separately resonate with their respectively coupled HV or LV PA cell, as the case may be. Moreover, the resonance of the capacitors 220.1, 220.2, 226.1, 226.2 enables the multiplication of the signals output via each of the LV drivers 224.1, 224.2 and the HV drivers 218.1, 218.2 in accordance with the SC-DPA topology as noted herein. The separation of the HV and LV domain cells in this manner enables the capacitors 220.1, 220.2, and 226.1, 226.2 to be optimized to the voltage domain and driver size of each HV and LV cell in each case. This addresses the issue of the same capacitor size and value being used for the conventional DPA architecture 100 for all transmissions, which prevents a true optimum size and value from being implemented in conventional designs.

Moreover, the DPA architecture 200 further includes a combiner 230, as noted above, which comprises two primary branches 230.1, 230.2 as well as a secondary branch 230.3. As shown in FIG. 2, the primary branch 230.1 is coupled to the resonant capacitors 220.1, 220.2, loaded with the capacitance thereof, and in turn coupled to the output of each of the HV PA cells. The other primary branch 230.2 is coupled to the resonant capacitors 226.1, 226.2, loaded with the capacitance thereof, and in turn coupled to the output of each of the LV PA cells. The secondary branch 230.3 is coupled to both primary branches 230.1, 230.2, and thus couples the primary branches 230.1, 230.2 to an output of the DPA 210. The combiner 230 may comprise a matching network for the DPA 210, and thus this output at the secondary branch 230.3 may comprise, for instance, any suitable components identified with the transmission of a desired wireless signal, such as one or more further matching networks, additional amplifiers, antennas, etc.

The use of the different HV and LV cells in this manner thus enables the separate control of the HV and LV PA cells based upon a desired transmit power level. To do so, the HV PA cells may implement a level shifter 216.1, 216.2, which may be coupled to a high voltage source VDDH as shown and be controlled via the coupled select logic 214.1, 214.2 in each case. The select logic 214.1, 214.2 may be configured to operate in accordance with the coupled low voltage source VDDL, and be implemented as any suitable type of logic gates and/or other suitable components to selectively activate the coupled HV driver 218.1, 218.2 via the generation of differential HV driver signals, as further discussed herein.

The select logic 214.1, 214.2 may utilize a local oscillator signal provided by the DPLL 206 in conjunction with the control data provided by the DSP 202 to selectively generate desired signals, which are then coupled to the level shifters 216.1, 216.2. Thus, the select logic 214.1, 214.2 may output low voltage level signals identified with a predetermined low voltage range, which may include a voltage range between a lower reference voltage (referred to herein as Vss, which may be 0 Volts, RF ground, etc.) and the low voltage source VDDL (also referred to herein as Vdm, as this may represent a maximum voltage specification with respect to the various transistors that are implemented, as shown and discussed in further detail herein).

The level shifters 216.1, 216.2 operate in accordance with the coupled high voltage source VDDH, and may comprise any suitable arrangement of logic gates, transistors, and/or other suitable components that convert the low voltage level signals provided by the select logic 214.1 214.2 (also referred to herein as the LV input signals with respect to the level shifters 216.1, 216.2) to respective differential HV driver signals. Thus, the level shifters 216.1, 216.2 may output high voltage differential driver signals identified with a predetermined high voltage range, which may include a voltage range between the high voltage source VDDH and a lower reference voltage. This lower reference voltage may be a scaled proportion of the low voltage source VDDL (such as twice the VDDL voltage or 2 Vdm as noted herein). In some illustrative scenarios, the predetermined low voltage range may have the same voltage range or “voltage swing” as the predetermined high voltage range, although the upper and lower voltage values within these ranges may differ from one another. Thus, each of the level shifters 216.1, 216.2 may be configured to output respective differential HV signals with an amplitude similar or identical to (excepting for tolerances) the LV input signals, which again are provided via the selection logic 214.1, 214.2, as discussed in further detail herein.

The level shifters 216.1, 216.2 of the HV PA cells may thus output differential HV signals to their respectively coupled HV drivers 218.1, 218.2. The HV drivers 218.1, 218.2 are likewise configured to operate in accordance with the higher voltage VDDH. Thus, the level shifters 216.1, 216.2 enable the HV PA cells to drive higher voltage output signals (via the HV drivers 218.1, 218.2) using the lower voltage LV input signals.

However, the LV PA cells may operate using the low voltage source VDDL, and thus do not require the use of a level shifter. For instance, the LV PA cells may also include select logic 222.1, 222.2 as shown, which may receive the control data provided by the DSP 202. However, unlike the HV PA cells, the select logic 222.1, 222.2 may provide differential signals that are not level shifted, which may include differential signals having the predetermined low voltage range as noted above. The LV drivers 224.1, 224.2 may thus output (via the LV drivers 224.1, 224.2) differential LV signals using the LV selection logic signals. Additional details regarding the selection logic 214.1, 214.2, the level shifters 216.1, 216.2, and the output stages (i.e. the HV drivers 218.1, 218.2 and the LV drivers 224.1, 224.2) are discussed in further detail below.

### II. DPA Level Shifter Architecture

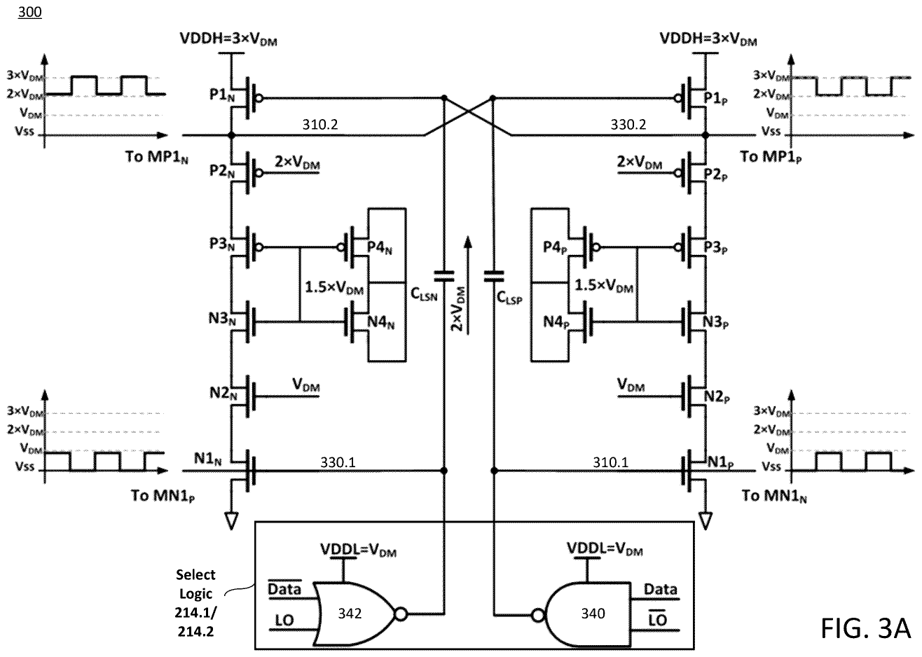

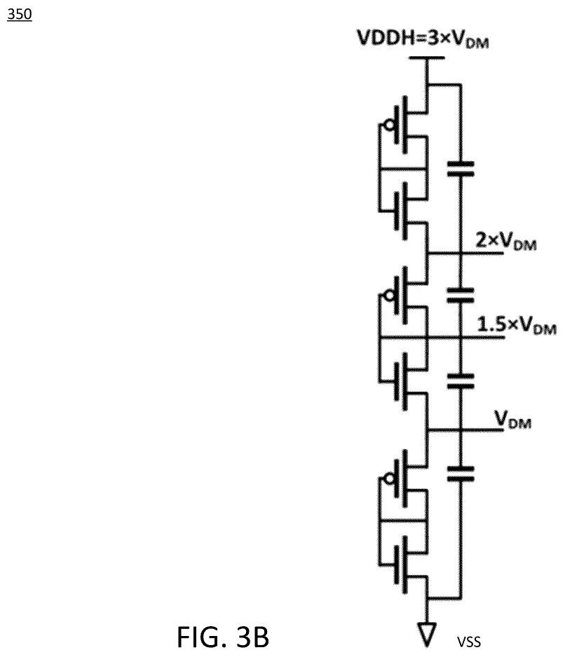

FIG. 3A illustrates a DPA level shifting circuit, in accordance with the disclosure. The DPA level shifter 300 as shown in FIG. 3A may utilize various bias voltages that are generated from the LV source VDDL (Vm as shown in FIG. 3B). Thus, FIG. 3B illustrates a floating gate circuit 350 for providing these various bias voltages, which also generates the HV source VDDH. Thus, and as shown in FIG. 3B, an arrangement of transistors may be implemented to generate the bias voltages as shown, which may then be coupled to any suitable portions of the DPA architecture 200 as discussed herein. It is noted that the bias circuit 350 as shown in FIG. 3B is optional, and the various bias voltages may alternatively or additional be generated via one or more DC-DC converters or other suitable power supplies. That is, a DC-DC converter may function to provide any of the voltages VDDH, VDDL, Vss, etc.

Thus, each of the transistors as shown in FIG. 3B may not be actively driven and thus remain floating. As a result, the bias voltages Vdm, 1.5×Vdm, 2×Vdm, and VDDH may be self-generated bias voltages that result from the stacked architecture of the floating gate circuit 350. Therefore, the need for additional DC-DC converters or other voltage supplies may be obviated and the self-generated bias voltages VDDH, 1.5×Vdm, and 2×Vdm may be generated by leveraging the floating gate architecture of the transistors of the floating gate circuit 350.

Referring now back to FIG. 3A, the differential level shifting circuit 300 is configured to generate two sets of driver signals 310.1, 310.2 and 330.1, 330.2, which provide level-shifted versions of the received data signals that are provided via the select logic 214.1/214.2 as shown. Each set of the driver signals 310.1, 310.2, and 330.1, 330.2 may be referred to herein as an HV differential signal, which comprises a pair of complementary HV signals in each case, i.e. the driver signals 310.1, 310.2, and 330.1, 330.2, as the case may be. The differential level shifter 300 may be identified with the level shifter 216.1, 216.2 of either of the PA cells 212.1.1, 212.2.1 as shown in FIG. 2, and thus the select logic 214.1/214.2 may be identified with the corresponding select logic as the case may be.

The level shifter 300 may be symmetric, i.e. include two different sets of transistors with the same configuration as shown. For instance, the left side of the differential level shifting circuit 300 may include an arrangement of six transistors P1N, P2N, P3N, N3N, N2N, and N1N having their source-drain terminals coupled in series with one another. The left side of the differential level shifter 300 also includes two transistors P4N, N4N, which are coupled to the two middle transistors P3N, N3N via their respective gates and are set to a bias of 1.5×Vdm as shown. This configuration enables the driver signals 310.2, 330.2 to be level-shifted with respect to the LV input signals that are output via the selection logic 214.1/214.2 while retaining the same voltage range. Again, this avoids placing excessive voltage stress on the terminals of the transistors. The right side of the differential level shifter 300 may include an identical arrangement of such transistors.

As shown in FIG. 3A, the select logic 214.1/214.2 may comprise a NAND gate 340 and a NOR gate 342, each being configured to operate in accordance with the VDDL voltage level. Thus, the select logic receives two type of signals: data signals (Data, Data-bar) and local oscillator (LO) signals (LO, LO-bar). The data signals (Data, Data-bar) are control signals that control whether a particular HV domain PA cell should be activated based on the control data provided via the DSP 202, and the LO signals (LO, LO-bar) are generated via the DPLL 206 and provide the RF carrier frequency timing. The NAND gate 340 and NOR gate 342 thus process these input signals to output the LV input signals, which in turn are used by the level shifter 300 to generate the driver signals 310.1, 310.2 and 330.1, 330.2. Specifically, the NAND gate 340 combines the Data and LO-bar inputs to generate one LV input signal for producing the HV differential driver signals 310.1, 310.2 (with the driver signal 310.1 being the output LV input signal), while the NOR gate 342 combines the Data-bar and LO inputs to generate another LV input signal for producing the HV differential driver signals 330.1, 330.2 (with the driver signal 330.1 being the other output LV input signal). The level shifter 300 thus converts the received LV input signals to HV domain voltage levels while substantially preserving their amplitude relationships, thereby generating the HV differential driver signals 310.1, 310.2 and 330.1, 330.2 that are coupled to and control the HV output driver stage. This architecture enables the HV domain PA cells to be controlled using LV input signals while operating at HV domain voltage levels suitable for high-power RF transmission.

For instance, the NAND gate 340 and the NOR gate 342 enable amplitude control for each HV cell by applying data=1/0, data-bar=0/1, thereby turning the respectively coupled HV cell on or off. This amplitude control enables the contribution of each HV cell to be controlled as part of an array of DPA cells used in an RF-DAC configuration, as noted herein. Moreover, the LO and LO-bar inputs may be equal in frequency and phase-shifted from one another by 180 degrees. And due to its supply voltage of VDDL, the NAND gate 340 generates the driver signal 310.1 having a voltage swing (i.e. peak-to-peak amplitude) approximately equal to the supply voltage of VDDL. However, due to the floating gate configuration of transistors and the bias voltages of 1.5×Vdm and 2×Vdm as shown, the driver signal 310.2 has a voltage swing (i.e. peak-to-peak amplitude) approximately equal to VDDH.

Likewise, the NOR gate 342 generates the driver signal 330.1 having a voltage swing (i.e. peak-to-peak amplitude) approximately equal to the supply voltage of VDDL and the driver signal 330.2 having a voltage swing (i.e. peak-to-peak amplitude) approximately equal to VDDH. As a result of the logical function applied by each of the NAND gate 340 and the NOR gate 342, the driver signals 310.1, 310.2 have the same phase as one another, and the driver signals 330.1, 330.2 have the same phase as one another. However, the driver signals 310.1, 310.2 are phase-shifted from the driver signals 330.1, 330.2 by 180 degrees, which is also illustrated in FIG. 3A.

Due to the 180-degree phase difference between the driver signals 310.1, 310.2, and 330.1, 330.2, this prevents the transistors P1P and P1N from having a voltage across any of their respective gate, drain, or source terminals exceeding VDDL. Furthermore, the effect of the coupling of the out-of-phase signals in this manner enables the output of the P1P and P1N transistors to have the same voltage swing (i.e. peak-to-peak amplitude) as the driver signals 310.1, 330.1, respectively, but DC level-shifted. That is, the driver signals 310.2, 330.2 may each vary between 2VDDL and 3VDDL as the source terminal of each of the transistors P1P and P1N is coupled to the higher voltage level of 3VDDL, as shown in FIG. 3A.

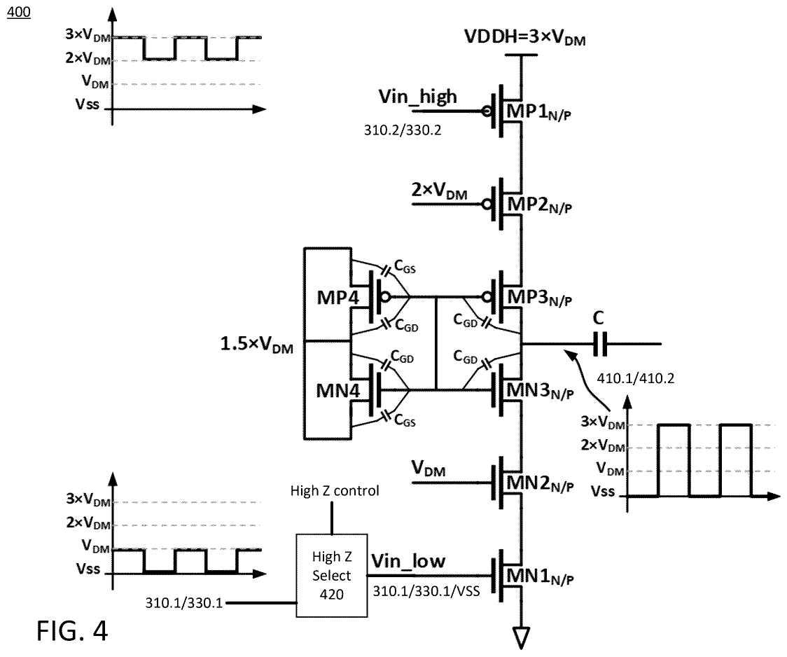

The level shifter 300 is thus configured to output a set of driver signals 310.1, 310.2 in response to the LV input signal output via the NAND gate 340, whereas the set of driver signals 330.1, 330.2 are output in response to the other LV input signal output via the NOR gate 342. As will be further discussed with respect to the output driver stage as shown in FIG. 4, each set of these driver signals is coupled to a corresponding portion of the HV driver 218.1, 218.2, as the case may be. That is, and referring now back to FIG. 2 and using the PA cell 212.1.1 for ease of explanation, it is noted that the HV driver 218.1 outputs a differential signal, with one half of the differential signal being coupled to a respective one of the capacitors 220.1. Thus, the driver signal 330.2 is coupled to a corresponding PMOS transistor in the HV driver 218.1 for pull-up control, which works in conjunction with the complementary driver signal 330.1 that is coupled to an NMOS transistor in the HV driver 218.1 for pull-down control.

Together, the driver signals 330.1, 330.2 provide complementary push-pull control for the “p” input side of the HV driver 218.1. Furthermore, the driver signals 310.1, 310.2 are coupled to the other input of the HV driver 218.1, with the driver signal 310.2 being coupled to a corresponding PMOS transistor for pull-up control, and the driver signal 310.1 being coupled to a corresponding NMOS transistor for pull-down control. Thus, together these driver signals 310.1, 310.2 provide complementary push-pull control for the “n” side of the HV driver 218.1. Therefore, the left side of the level shifter 300 may be referred to as a p-channel driver, whereas the right side of the level shifter 300 may be referred to as an n-channel driver.

Thus, and as will be further discussed with respect to the HV output driver stage 400 as shown in FIG. 4, each set of the HV differential driver signals 310.1, 310.2 and 330.1, 330.2 is provided as an input to a corresponding portion of the HV driver 218.1, 218.2, as the case may be. That is, and referring now back to FIG. 2 using the PA cell 212.1.1 for ease of explanation, it is noted that the HV driver 218.1 receives two differential signal inputs (310.1, 310.2 and 330.1, 330.2) from the level shifter 216.1, and provides an HV differential output signal that is coupled to the resonant capacitors 220.1. Thus, each half of the HV differential output signal is coupled to a respective one of the capacitors 220.1, as discussed in further detail below.

The level shifter 300 also includes capacitors CLSN and CLSP, which function as feedforward capacitors to improve the speed of the level shifter 300. That is, the capacitors CLSN and CLSP ensure that the delay between when the LV input signals are received via the select logic 214.1, 214.2 and the driver signals 310.1, 310.2, 330.1, 330.2 are generated is minimized or at least significantly reduced. To do so, and as shown in FIG. 3A, the capacitors CLSN and CLSP function to apply a “shortcut” path to change the voltage level output by the transistors P1P and P1N.

### III. An HV Output Driving Stage

FIG. 4 illustrates a high voltage (HV) output driving stage, in accordance with the disclosure. The HV output driving stage 400 as shown in FIG. 4 may be identified, in one illustrative scenario, with a portion of an HV driver of an applicable PA cell within one of the PA cell arrays 212 as discussed with respect to FIG. 2. For ease of explanation, the previous illustrative scenario is continued with respect to the PA cell 212.1.1, and thus the HV output driving stage 400 as shown in FIG. 4 may be identified, in accordance with this illustrative scenario, with a portion of the HV driver 218.1 as shown in FIG. 2.

Specifically, the HV output driving stage 400 as shown in FIG. 4 may be identified with one half of the HV driver 218.1, i.e. the HV driver 218.1 may comprise two of the HV output driving stages 400 as shown in FIG. 4, each receiving a set of the driver signals 310.1, 310.2, 330.1, 330.2, and providing one half of the HV differential output signal that is coupled to one of the two capacitors 220.1 as shown in FIG. 2. As each half of the HV driver 218.1 comprises an identical configuration of the HV output driving stage 400 as shown in FIG. 4, only a single configuration (i.e. for one half) is shown for brevity and ease of explanation.

As noted above, the level shifting circuit 300 may be configured to output, as the driver signals 310.1, 310.2, 330.1, 330.2, two sets of HV differential driver signals: a first HV differential driver signal comprising signals 310.1 and 310.2 in response to signals output via the NAND gate 340, and a second HV differential driver signal comprising signals 330.1 and 330.2 in response to signals output via the NOR gate 342. Thus, the HV output driving stage 400 as shown in FIG. 4 may receive, as one input of the HV driver 218.1, the driver signals 310.1, 310.2 output by the level shifter 216.1. These two driver signals 310.1, 310.2 may thus be mapped to the lower input of the HV driver 218.1, which is shown in FIG. 2 as a single connection but may include multiple wires, buses, etc. to accommodate this differential signal connection.

As shown in FIG. 4, one of the HV differential driver signals comprising driver signals 310.1 and 310.2 controls the “n” side of the differential HV driver 218.1 (i.e. the bottom connection as shown in FIG. 2). Thus, for this portion of the HV driver 218.1, the driver signal 310.1 is coupled to a corresponding NMOS transistor (the Vin_low input) for pull-down control, whereas the complementary driver signal 310.2 is coupled to a corresponding PMOS transistor (the Vin_high input) for pull-up control. Together, these driver signals 310.1, 310.2 provide complementary push-pull control for the “n” side of the differential HV driver 218.1. Likewise, the other HV differential driver signal comprising driver signals 330.1 and 330.2 controls the “p” side of the differential HV driver 218.1 (i.e. the top connection as shown in FIG. 2), with the driver signal 330.1 being coupled to an NMOS transistor (the Vin_low input) for pull-down control, and the complementary driver signal 330.2 being coupled to a corresponding PMOS transistor (the Vin_high input) as shown in FIG. 4 for pull-up control. Together, the driver signals 330.1, 330.2 provide complementary push-pull control for the “p” side of the HV driver 218.1.

Furthermore, the HV output driving stage 400 as shown in FIG. 4 includes a stacked floating gate feedback arrangement of transistors. This arrangement is the same as each driving half of the level shifter 300 as shown in FIG. 3A, and also includes an arrangement of six transistors having their source-drain terminals coupled in series with one another. For the “n” input to the HV driver 218.1, the transistors are connected in this manner from the top to bottom as MP1N, MP2N, MP3N, MN3N, MN2N, MN1N. For the “p” input to the HV driver 218.1, the transistors are connected in this manner from the top to bottom as MP1P, MP2P, MP3P, MN3P, MN2P, MN1P.

In both cases, the HV output driving stage 400 includes a stacked floating gate feedback arrangement of the center transistors MP4, MN4, MP3N/P, and MN3N/P as shown, which provides a capacitive divider identified with a capacitive feedback ratio. The transistors MP4, MN4, may be substantially the same as one another (the same manufacturer, part number, type, size, etc.) and thus have substantially the same intrinsic capacitance values (within some manufacturing tolerances such as 1%, 2%, 5%, etc.). As a result, the transistors MP4, MN4 each have an equal intrinsic gate-source (Cgs) and gate-drain (Cgd) capacitance formed between their respective terminals as a result of the layout of these components (with Cgs and Cgd also being equal to one another). Furthermore, each of the transistors MP3N, MN3N, or MP3P, MN3P, as the case may be, may be substantially the same as one another (the same manufacturer, part number, type, size, etc.) and thus have substantially the same intrinsic capacitance values (within some manufacturing tolerances such as 1%, 2%, 5%, etc.). As a result, the transistors MP3N, MN3N or MP3P, MN3P, as the case may be, each have equal intrinsic gate-drain capacitances (and gate-source capacitances, which are also equal to their gate-drain capacitances).

The HV output driving stage 400 may thus implement any suitable number of transistors in a floating gate arrangement in this manner such that a desired capacitive feedback ratio is achieved, with the arrangement as shown in FIG. 4 enabling the use of a VDDH voltage that is three times that of the VDDH voltage (i.e. Vdm). For the HV output driving stage 400 configuration as shown in FIG. 4, the capacitive ratio is 2:1 as a result of the transistors MP4, MN4 having a capacitance of C2=4×Cgd (assuming Cgs and Cgd are equal), whereas the transistors MP3N, MN3N or MP3P, MN3P, as the case may be, have a capacitance of C1=2×Cgd. In other words, the capacitive feedback ratio is such that C1=2C2. In accordance with such a configuration, a capacitive divider is formed between the transistors MP3N, MN3N (or MP3P, MN3P), and the transistors MP3N, MN3N (or MP3P, MN3P) to define the feedback capacitive ratio of 2:1. This capacitive feedback ratio also enables the self-generation of the DC bias voltage that is half of the HV level of VDDH as shown in FIG. 4 (i.e. 1.5×Vdm). The capacitive feedback ratio may be set by selecting the appropriate number, type, and/or size of transistors. The transistors MP4, MN4 may be selected to be a larger size such that their intrinsic capacitance values are larger than that of the transistors MP1N, MP2N, MP3N, MN3N, MN2N, MN1N or MP1P, MP2P, MP3P, MN3P, MN2P, MN1P, as the case may be, or may be identical to the transistors MP1N, MP2N, MP3N, MN3N, MN2N, MN1N or MP1P, MP2P, MP3P, MN3P, MN2P, MN1P, as the case may be, but be greater in number to stack their capacitances as desired.

As a result of the feedback capacitive ratio, the HV output driver stage 400 also achieves the desired amplification of the input driver signals 310.1, 310.2 and 330.1, 330.2. That is, each half of the HV output driver stage 400 as shown in FIG. 4 may generate an output signal 410.1, 410.2 in accordance with the feedback capacitive ratio such that the output signal 410.1, 410.2 has a voltage swing or range that varies between the LV level of the input driver signals 310.1, 310.2 and 330.1, 330.2 (VDDH, i.e. Vdm) and a scaled voltage that is, in this illustrative scenario, three times VDDL (i.e. VDDH) due to the stacked floating gate feedback arrangement of transistors. Thus, as a result of the floating gate configuration of the transistors MP3N, N3N (or MP3P, MN3P), the gates of the transistors MP3N, N3N (or MP3P, MN3P) track the output signal 410.1, 410.2. This eliminates stress on each of the transistors in the HV output driver stage 400, as no transistor develops a voltage across any two respective terminals that exceeds the peak-to-peak amplitude (i.e. swing or voltage range) of the input driver signals 310.1, 310.2 and 330.1, 330.2 which is VDDL (i.e. Vdm) as shown in FIG. 4.

Furthermore, it is noted that conventional solutions to simply couple HV PA cells and LV PA cells to a matching network are not beneficial if the HV PA cells are active during low voltage power transmissions, as the HV PA cells would otherwise load the LV cells and result in reduced performance. Thus, the HV PA cells may be selectively activated or deactivated as a function of transmit power. As an illustrative scenario, and as shown in FIG. 4, the voltage difference between the driver signals 310.1, 310.2 or 330.1, 330.2 is typically twice Vdm (i.e. 2×VDDL), as the driver signals are in phase with one another when the HV driver 218.1 is active. However, any of the HV driver cells within any of the PA cell arrays 212 may be selectively deactivated when not contributing to a data transmission, such as when only a lower power communication protocol is implemented, and an accompanying wireless signal transmission is occurring using only the LV PA cells.

Thus, the HV output driver stage 400 may further comprise a high Z select block 420, which is configured to “override” the voltage value of the driver signals 310.1, 330.1 to the reference voltage Vss, which may comprise an RF ground. The high Z select block 420 may be configured as any suitable arrangement of components such as switches, logic gates, etc., to facilitate this functionality. The high Z select block 420 may thus be coupled to the outputs of the level shifter 300 as shown in FIG. 3A, and may also be coupled to a high Z control line. The high Z control line may be identified with and/or provided by any suitable components of the DPA architecture 200, such as the DSP 202, or any suitable component(s) that may generate a corresponding active/inactive control signal that is coupled to the high Z select block 420 via the high Z control line. The active/inactive control signal may have any suitable characteristics for this purpose, such as being set to one of two logical values for instance.

Thus, when a particular HV PA cell is activated, the high Z control line may be set to a value that is recognized by the high Z select block 420 and results in the driver signals 310.1, 330.1 being coupled to the Vin_low input of the HV output driver stage 400 as shown in FIG. 4 and discussed above. However, when a particular HV PA cell is deactivated, which may be the case for instance when the LV driver cells are actively transmitting a wireless signal at a lower transmission power level, the high Z select block 420 overrides the voltage value of the driver signals 310.1, 330.1 to the reference voltage Vss.

In this inactive configuration, the value of the Vin_low input of the HV output driver stage 400 is thus set to Vss while the Vin_high input of the HV output driver stage 400 is set to VDDL. This causes the transistors in the HV output driver stage 400 to not conduct because the gate of the MN1N/P transistor does not conduct due to the gate voltage being set to Vss. As a result, the output of the HV output driver stage 400 (i.e. the output coupled to a respective capacitor 220.1, 220.2) is placed in a high-impedance state while inactive.

### IV. An LV Output Driving Stage

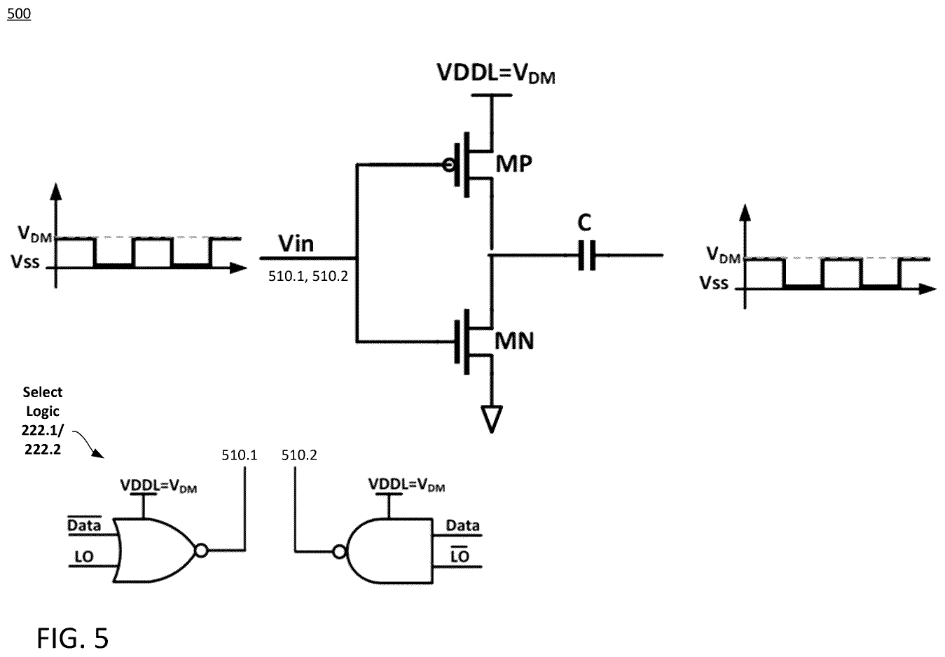

FIG. 5 illustrates a low voltage (LV) output driving stage, in accordance with the disclosure. The LV output driving stage 500 as shown in FIG. 5 may be identified, in one illustrative scenario, with a portion of an LV driver of an applicable PA cell within one of the PA cell arrays 212 as discussed with respect to FIG. 2. For ease of explanation, the previous illustrative scenario is continued with respect to the PA cell 212.1.1, and thus the LV output driving stage 500 as shown in FIG. 5 may be identified, in accordance with this illustrative scenario, with a portion of the LV driver 224.1 as shown in FIG. 2.

Specifically, the LV output driving stage 500 as shown in FIG. 5 may be identified with one half of the LV driver 224.1, i.e. the LV driver 224.1 may comprise two of the LV output driving stages 500 as shown in FIG. 5, each receiving one of the set of the driver signals 510.1, 510.2 and providing one half of the LV differential output signal that is coupled to one of the two capacitors 226.1 as shown in FIG. 2. As each half of the LV driver 224.1 comprises an identical configuration of the LV output driving stage 500 as shown in FIG. 5, only a single configuration (i.e. for one half) is shown for brevity and ease of explanation.

The LV output driving stage 500 as shown in FIG. 5 receives LV input signals 510.1, 510.2 that are generated via the select logic 222.1 as shown in FIG. 2. Unlike the HV domain PA cells, the LV domain PA cells do not require a level shifter, as the select logic 222.1, 222.2 and the LV drivers 224.1, 224.2 both operate in accordance with the low voltage source VDDL. Thus, the LV input signals 510.1, 510.2 are provided directly from the select logic 222.1 to the LV output driving stage 500 without requiring level shifting.

The LV output driving stage 500 thus comprises a single pair of transistor drivers as shown in FIG. 5, which includes a PMOS transistor MP and an NMOS transistor MN. The PMOS transistor MP and NMOS transistor MN have their source-drain terminals coupled in series with one another, with the output capacitor C coupled therebetween as shown. One of the LV input signals 510.1 may be coupled to the gates of the PMOS transistor MP and NMOS transistor MN, whereas the other one of the LV input signals 510.2 may be coupled to the other identical half of the LV output driving stage 500 to provide complementary switching control in a manner analogous to the HV output driving stage 400 as discussed herein.

However, the use of a single pair of transistor drivers in the LV output driving stage 500 provides improved efficiency compared to the stacked floating gate feedback arrangement of the HV output driving stage 400. That is, the stacking of multiple devices increases the ON state switching impedance (by a factor of 3 for the topology shown in FIG. 4), which degrades power efficiency. Thus, the single pair of transistor drivers are used for the LV domain PA cells to optimize efficiency for lower power transmissions, while the stacked floating gate feedback arrangement is used for the HV domain PA cells to enable higher voltage operation without excessive voltage stress on individual transistor terminals.

### V. A Combiner Structure

The DPA architecture 200 may implement the combiner 230 to further leverage the HV PA cells being placed into high impedance states when inactive so as to not load the LV PA cells during lower power transmissions. For instance, and referring back to FIG. 2, inactive HV PA cells result in their respective outputs, which are coupled to the resonant capacitors 220.1, 220.2, being placed into a high impedance state, and the HV primary branch 230.1 is physically separated from the LV primary branch 230.2. As a result, the interaction or loading with the active LV PA cells when the HV PA cells are in a high impedance state is minimized or at least significantly reduced.

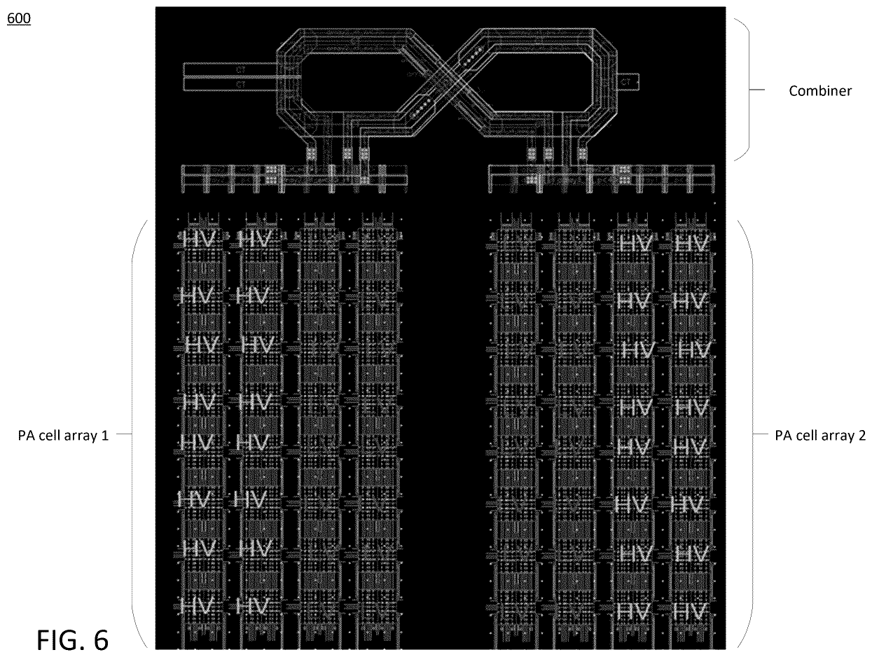

FIG. 6 illustrates a layout view of a dual bias DPA including a combiner structure, in accordance with the disclosure. In the illustrative layout view shown in FIG. 6, each PA cell array contains 2 rows of LV domain cells and 2 rows of HV domain cells. Thus, the left PA cell array 1 may be identified with the PA cell array 212.1, whereas the right PA cell array 2 may be identified with the PA cell array 212.2. However, in the illustrative scenario as shown in FIG. 6, each PA cell array includes 16 HV PA cells and 16 LV PA cells instead of one each as shown in FIG. 2.

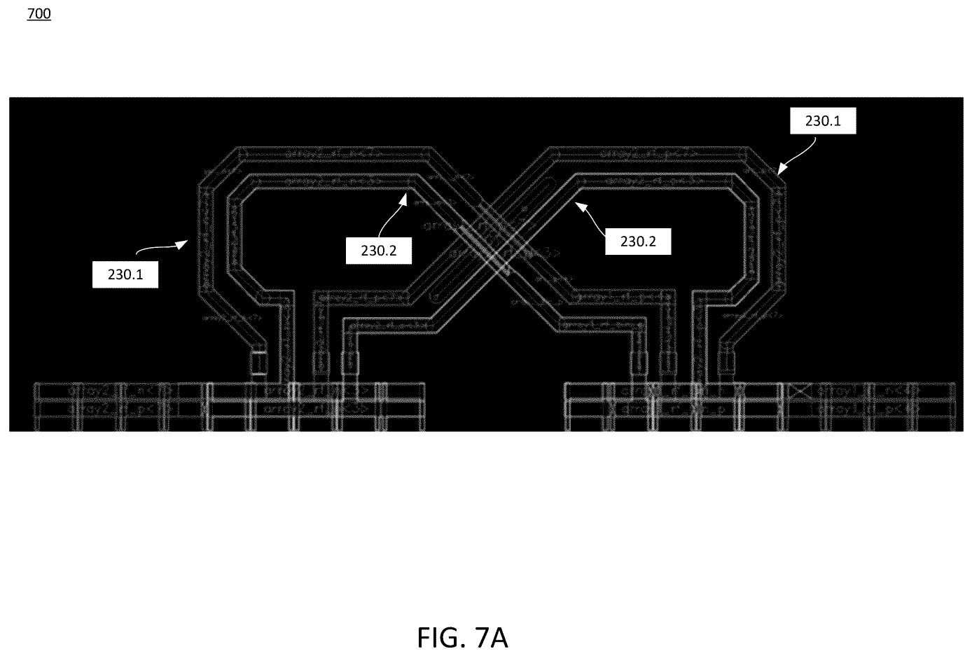

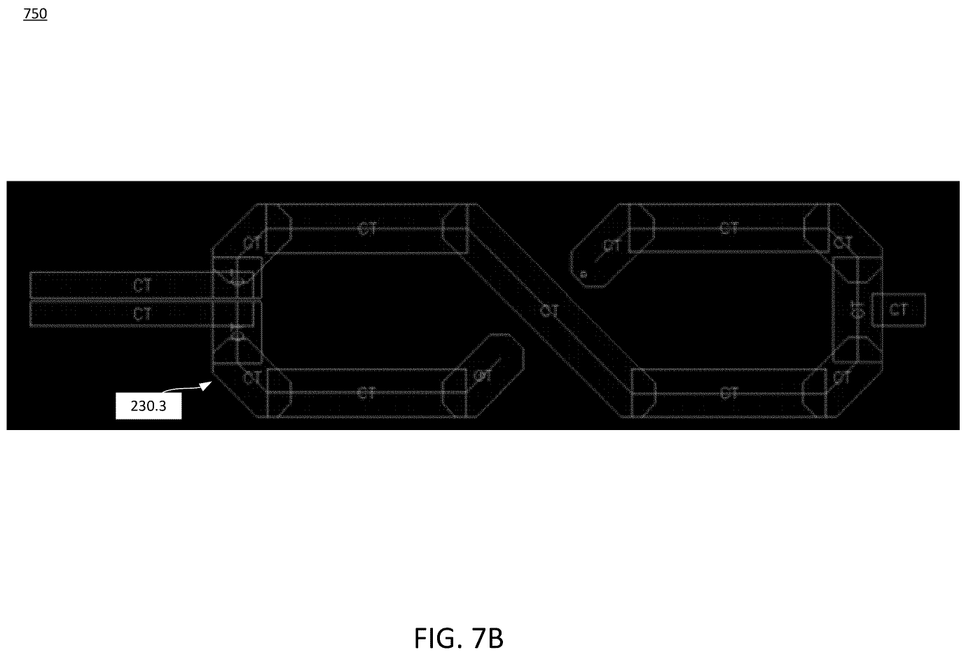

Moreover, FIG. 6 also illustrates a combiner structure, which may be identified with the combiner 230 as shown in FIG. 2. Additional details regarding the combiner 230 are shown in FIGS. 7A and 7B. For instance, FIG. 7A illustrates that the combiner 230 includes two primary branches 230.1, 230.2. The outer portion of the combiner 230 may be identified with the primary branch 230.1, which resonates with the HV domain resonance capacitances 220.1, 220.2, whereas the inner portion of the combiner 230 may be identified with the primary branch 230.2, which resonates with the LV domain resonance capacitances 226.1, 226.2. FIG. 7B illustrates additional detail regarding the secondary branch 230.3, which electrically couples both primary branches 230.1, 230.2 to an output of the DPA 210, as noted herein.

It is noted that each of the primary branches 230.1, 230.2 and the secondary branch 230.3 comprises a folded or “figure-eight” shape. This saves silicon area and also facilitates an additional increase in efficiency at lower power transmission modes when a higher power backoff is required. In various illustrative scenarios, any of the primary branches 230.1, 230.2 and the secondary branch 230.3 may be disposed in any suitable number of layers of a chip or other suitable DPA implementation. As one illustrative scenario, the primary branches 230.1, 230.2 may be implemented in a top copper metal layer to minimize parasitics, whereas the secondary branch 230.3 may be implemented in an aluminum layer. However, the primary branches 230.1, 230.2 and the secondary branch 230.3 may be implemented in any suitable layers and/or may be implemented as any suitable type of metal, which may be different layers and/or metals than one another or the same metals and/or layers, in various illustrative scenarios.

### VI. Performance Comparisons

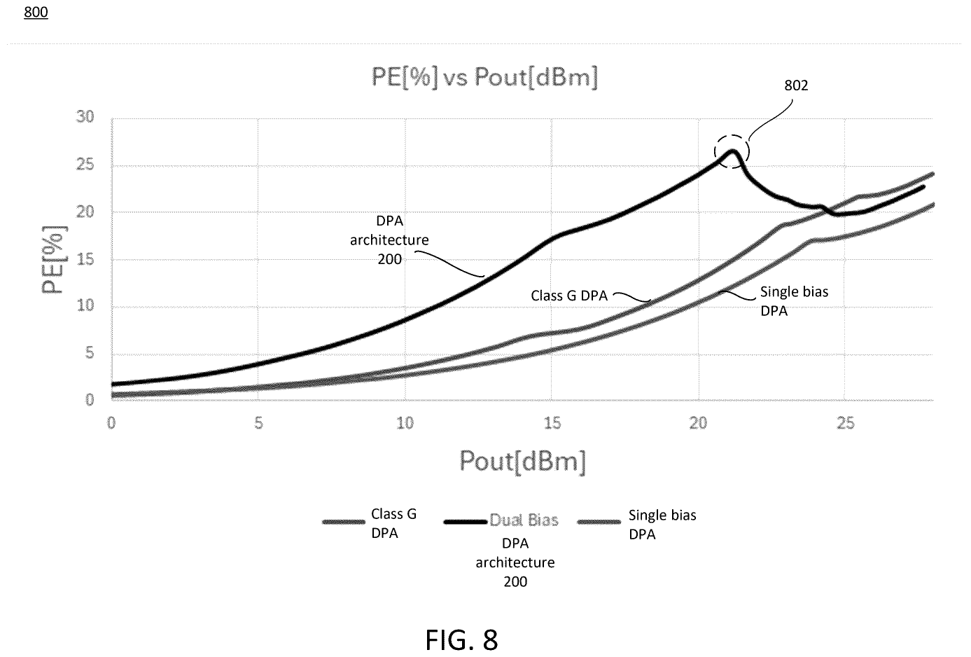

FIG. 8 illustrates a graph of power efficiency (PE) vs transmission output power (Pout) that compares the performance between a conventional, Class G, and dual bias topologies, in accordance with the disclosure. The graph 800 illustrates power efficiency vs transmission output power between three solutions: a single bias DPA, a Class G DPA, and the dual bias DPA architecture 200 as discussed herein. As shown in FIG. 8, the dual bias DPA architecture 200 provides significant power efficiency improvements across a wide range of transmission output power levels compared to conventional DPA architectures.

The conventional single bias DPA exhibits relatively high efficiency at higher transmission output power levels, but experiences significant efficiency degradation at lower transmission output power levels (i.e., at high back-off conditions). The Class G DPA architecture provides improved efficiency compared to the conventional single bias DPA architecture at lower transmission output power levels due to its dynamic supply voltage switching capability, but still suffers from efficiency limitations across the full range of transmission output power levels.

In contrast, the dual bias DPA architecture 200 achieves superior power efficiency performance by implementing separate LV and HV domain PA cells with dedicated optimized loads and placing HV cells in high-impedance states during low power transmissions. This results in multiple efficiency peaks across various back-off levels, including peak efficiency at approximately 6 dB back-off, with additional efficiency peaks observable at approximately 3.5 dB and 12 dB back-off levels. The “knee” 802 at the curve for the dual bias DPA architecture 200, which is identified with the maximum efficiency around 21 dBm, may be identified with the switch from all LV PA cells being active and transmitting in accordance with a low power transmission to a higher power transmission in which the HV PA cells begin to be sequentially activated. Thus, a decrease in efficiency is seen once the HV PA cells are activated in this manner for higher power transmissions, which is expected given the degradation in power efficiency by way of the stacking of multiple devices and the corresponding increase in the on state switching impedance as noted herein. Nonetheless, the overall efficiency of the DPA architecture 200 represents an improvement over nearly the entire range of transmission power levels compared to conventional DPA architectures. These efficiency improvements directly address the power efficiency limitations of conventional Class G and single bias DPA architectures, particularly for shared PA implementations that must support multiple communication protocols with significantly different transmission power requirements such as Wi-Fi and Bluetooth.

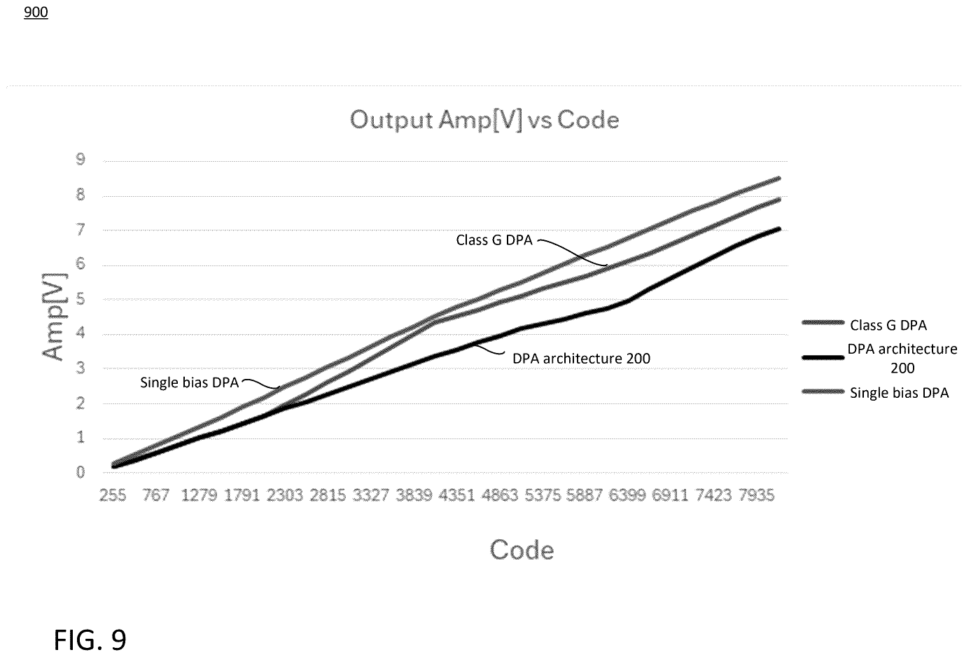

FIG. 9 illustrates a graph of output amplitude (Amp) vs code that compares the performance between a conventional, Class G, and dual bias topologies, in accordance with the disclosure. As shown in FIG. 9, the output amplitude response as a function of a digital control code is compared across the three DPA architectures. The digital control code, which may be identified with the K-bit control word generated by the DSP 202 as discussed herein, determines the number of active LV and HV PA cells within the PA cell arrays 212, and thus controls the output amplitude of the transmitted signal. The graph demonstrates that the DPA architecture 200 exhibits amplitude control characteristics that enable smooth transitions across the full dynamic range of transmission output power levels.

The conventional single-bias DPA architecture provides a substantially linear amplitude response across its operating range, but operates at a single fixed voltage supply level and thus lacks the efficiency optimizations enabled by the dual bias approach. The Class G DPA architecture exhibits amplitude response characteristics that reflect its dynamic supply voltage switching capability, which may result in discontinuities or non-linearities at the voltage switching transition points. In contrast, the DPA architecture 200 provides improved amplitude control by leveraging the separate activation of LV and HV domain PA cells, which enables the sequential activation of first the LV PA cells for lower amplitude signals followed by the progressive activation of HV PA cells as higher output amplitudes are required. This sequential activation approach enables the dual bias architecture to maintain amplitude control linearity while simultaneously achieving the power efficiency benefits as discussed herein. The amplitude response characteristics shown in FIG. 9 thus demonstrate that the DPA architecture 200 provides both efficient power delivery and precise amplitude control across the full range of transmission output power levels required for supporting multiple communication protocols.

### VII. A Communication Device

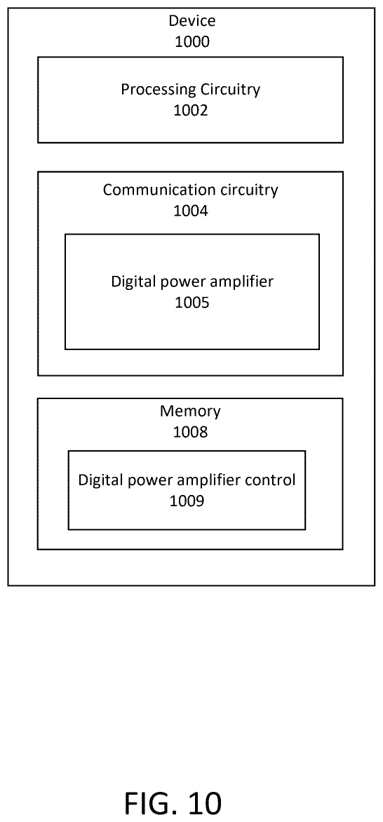

FIG. 10 illustrates a device, in accordance with the disclosure. The device 1000 may be identified with any suitable type of device that implements a DPA, such as the DPA architecture 200 as discussed herein. The device 1000 may be identified with any suitable type of device that receives, transmits, and/or processes wireless signals. Thus, the device 1000 may be identified with a wireless device, a user equipment (UE), a mobile phone, a tablet, a laptop computer, a wearable device, etc.

The device 1000 may further comprise processing circuitry 1002, which may be alternatively referred to herein as control circuitry. The processing circuitry 1002 may be implemented as any suitable number and/or type of computer processors, and may function to control the DPA architecture 200 and/or other components of the DPA architecture 200. The processing circuitry 1002 may be identified with one or more processors (or suitable portions thereof) implemented by the device 1000. In a non-limiting and illustrative scenario, the processing circuitry 1002 may be identified with part of or the entirety of the DSP 202, as shown and discussed above with respect to FIG. 2. The processing circuitry 1002 may be implemented as a host processor, a microcontroller, a digital signal processor, one or more microprocessors, a central processing unit (CPU), graphics processors such as a graphics processing unit (GPU), baseband processors, microcontrollers, an application-specific integrated circuit (ASIC), part (or the entirety of) a field-programmable gate array (FPGA), etc. Such components may be present in addition to or instead of the DSP 202, and may provide similar functionality as discussed herein with respect to the DSP 202.

The processing circuitry 1002 may be configured to carry out instructions to perform arithmetical, logical, and/or input/output (I/O) operations, and/or to control the operation of one or more components of device 1000 to perform various functions as described herein. The processing circuitry 1002 may include one or more microprocessor cores, memory registers, buffers, clocks, etc., and may generate electronic control signals associated with the components of the device 1000 to control and/or modify the operation of these components. This may include the generation of the K-bit control data as discussed herein. The processing circuitry 1002 may communicate with and/or control functions associated with the memory 1008, as well as any other components of the device 1000. Thus, the processing circuitry 1002 may control or cause other components to control the operation of the DPA architecture 200, as discussed herein.

The device 1000 comprises communication circuitry 1004, which may comprise any suitable number and/or type of components configured to receive, condition, generate, transmit, and/or process signals associated with any suitable type of wireless communications. The communication circuitry 1004 may be coupled to one or more portions of the processing circuitry 1002 and/or the device 1000. The device 1000 may include any suitable type of components that are known to be associated with such communication functions, such as front-end components, antennas, buffers, mixers, oscillators, receivers, transmitters, transceivers, etc., as well as other suitable hardware components that may function in conjunction with such communication components, such as port, terminals, etc., which may be implemented to couple the communication circuitry 1004 to other suitable components and/or portions of the device 1000. The communication circuitry 1004 may comprise or otherwise integrate a digital power amplifier 1005, which may be identified with the DPA architecture 200 as discussed herein. Additionally or alternatively, the communication circuitry 1004 may be identified with any suitable components of the device 1000 depending upon the particular application and implementation of the device 1000.

The memory 1008 is configured to store data and/or instructions such that, when executed by the processing circuitry 1002, cause the device 1000 to perform various functions such as controlling, monitoring, adjusting, and/or regulating the operation of the device 1000, which may include operation of the device 1000 to transmit wireless signals in accordance with any suitable number of communication protocols and respective transmission output power levels as noted herein. In a non-limiting and illustrative scenario, the memory 1008 may be identified with part of or the entirety of the DSP 202, as shown and discussed above with respect to FIG. 2. The memory 1008 may be implemented as any suitable type of volatile and/or non-volatile memory, including read-only memory (ROM), random access memory (RAM), flash memory, a magnetic storage media, an optical disc, erasable programmable read only memory (EPROM), programmable read only memory (PROM), etc.

The memory 1008 may be non-removable, removable, or a combination of both. The memory 1008 may be implemented as a non-transitory computer readable medium storing one or more executable instructions such as logic, algorithms, code, etc. The instructions, logic, code, etc., stored in the memory 1008 are represented by the various modules as shown. The processing circuitry 1002 may execute the instructions stored in the memory 1008, which are represented as the various modules and further discussed below, to enable any of the techniques as described herein to be functionally realized.

The digital power amplifier control module 1009 may store computer-readable instructions that, when executed by the processing circuitry 1002, enable the processing circuitry 1002 and/or the device 1000 to perform any of the functions as described herein with respect to the operation of the DPA architecture 200. Additionally or alternatively, the processing circuitry 1002 may execute the instructions stored in the digital power amplifier control module 1009 to selectively activate the various LV and HV PA cells of the DPA 210 to transmit wireless signals in accordance with any suitable number of communication protocols and respective transmission output power levels as noted herein.

### IX. A Process Flow

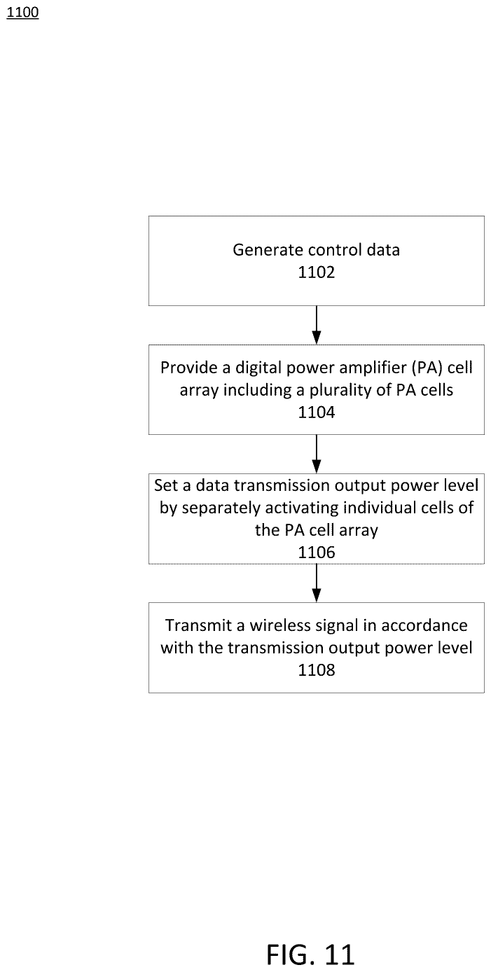

FIG. 11 illustrates a process flow, in accordance with the disclosure. The process flow 1100 as shown in FIG. 11 may be a manual process, a fully-automated process, or a partially-automated process. When fully or partially-automated, any portion or the entirety of the process flow 1100 may be implemented as a computer-implemented process executed by and/or otherwise associated with one or more processors. These processors may be associated with one or more computing components identified with any suitable computing device or architecture, such as a computing device, a wireless device, or a communication component configured to perform such functionality. This computing device may be identified, in some non-limiting and illustrative scenarios, with the device 1000 and/or the DPA architecture 200 as discussed herein. Thus, in accordance with such scenarios, the processing circuitry 1002 may execute instructions stored in any suitable memory (such as the memory 1008) to perform or cause any components of the DPA architecture 200 to perform any portions (or the entirety of) the process flow 1100. The process flow 1100 may include alternate or additional steps that are not shown in FIG. 11 for purposes of brevity, and may be performed in a different order than the steps shown in FIG. 11.

With respect to FIG. 11, the process flow 1100 may begin by generating (block 1102) control data. This may include, in a non-limiting and illustrative scenario, generating the control data via the DSP 202 as discussed herein with respect to the DPA architecture 200 as shown in FIG. 2. The control data may comprise a K-bit control word or other suitable digital control signals configured to control the activation state and/or operation of the PA cells within the PA cell arrays 212.1, 212.2, as discussed herein.

The process flow 1100 may include providing (block 1104) a digital power amplifier (PA) cell array comprising a plurality of PA cells. This may include, in a non-limiting and illustrative scenario, providing the PA cell arrays 212.1, 212.2 as discussed herein with respect to the DPA architecture 200 as shown in FIG. 2. Again, each PA cell from among the plurality of PA cells may comprise a low voltage (LV) domain PA cell configured to generate, based on the control data, an LV output signal, and a high voltage (HV) domain PA cell configured to generate, based on the control data, an HV output signal. Thus, block 1104 may comprise part of a CMOS fabrication and/or manufacturing process in which the DPA architecture 200 is formed as part of a CMOS integrated circuit (IC), a CMOS system-on-chip (SoC), or other suitable implementation, as discussed herein.

The process flow 1100 may include setting (block 1106) a transmit power level by separately activating the LV domain PA cell and the HV domain PA cell. This may include, in a non-limiting and illustrative scenario, using the control data generated by the DSP 202 to selectively activate the LV domain PA cells and/or the HV domain PA cells of the PA cell arrays 212.1, 212.2 based upon the desired transmit power level. For instance, for lower power transmissions that may be associated with a communication protocol such as Bluetooth, the control data may facilitate the LV domain PA cells generating their respective LV output signals while the HV domain PA cells are placed into a high-impedance state, as discussed herein. Alternatively, for higher power transmissions that may be associated with a different communication protocol such as Wi-Fi, the control data may facilitate both the LV domain PA cells and the HV domain PA cells being activated to generate their respective LV and HV output signals.

The process flow 1100 may include transmitting (block 1108) a wireless signal in accordance with the transmit power level. This may include, in a non-limiting and illustrative scenario, transmitting the wireless signal via any suitable components coupled to the output of the DPA 210, such as the combiner 230, matching networks, antennas, and/or other suitable components as discussed herein. The wireless signal may be transmitted at the desired transmit power level based upon the separate activation of the LV domain PA cells and/or the HV domain PA cells as determined by the control data, as noted herein.

### X. General Operation of an Apparatus

An apparatus is provided. The apparatus comprises a data interface configured to receive control data; and a digital power amplifier cell array comprising a plurality of power amplifier cells, with a power amplifier cell from among the plurality of power amplifier cells comprising: a low voltage domain power amplifier cell configured to generate, based on the control data, a low voltage output signal; and a high voltage domain power amplifier cell configured to generate, based on the control data, a high voltage output signal. The control data facilitates a separate activation of the low voltage domain power amplifier cell and the high voltage domain power amplifier cell to selectively adjust a transmit power level. In addition or in alternative to and in any combination with the optional features previously explained in this paragraph, the control data facilitates, for a transmit power level in accordance with a first communication protocol, the low voltage domain power amplifier cell generating the low voltage output signal based at least in part on the high voltage domain power amplifier cell being in a high-impedance state. In addition or in alternative to and in any combination with the optional features previously explained in this paragraph, the control data facilitates, for a transmit power level in accordance with a second communication protocol that is associated with a higher power transmission level than the first communication protocol, the low voltage domain power amplifier cell generating the low voltage output signal based at least in part on the high voltage domain power amplifier cell generating the high voltage output signal. In addition or in alternative to and in any combination with the optional features previously explained in this paragraph, the low voltage domain power amplifier cell comprises a low voltage output stage coupled to a set of low voltage resonance capacitors with a first capacitor value, and the high voltage domain power amplifier cell comprises a high voltage output stage coupled to a set of high voltage resonance capacitors with a second capacitor value. In addition or in alternative to and in any combination with the optional features previously explained in this paragraph, the apparatus further comprises a combiner coupled to the low voltage domain power amplifier cell and the high voltage domain power amplifier cell, the combiner comprising: a first primary branch configured to be loaded with an output capacitance of the low voltage domain power amplifier cell; a second primary branch configured to be loaded with an output capacitance of the high voltage domain power amplifier cell; and a secondary branch that couples the first primary branch and the second primary branch to an output of a digital power amplifier. In addition or in alternative to and in any combination with the optional features previously explained in this paragraph, the high voltage domain power amplifier cell further comprises a differential level shifter configured to receive a low voltage input signal based on the control data, and to generate a high voltage differential signal comprising a pair of high voltage signals with an amplitude that substantially matches an amplitude of the low voltage input signal. In addition or in alternative to and in any combination with the optional features previously explained in this paragraph, the high voltage domain power amplifier cell further comprises an output stage that includes a stacked floating gate feedback arrangement of transistors. In addition or in alternative to and in any combination with the optional features previously explained in this paragraph, the low voltage domain power amplifier cell further comprises an output stage that includes a single pair of transistor drivers.

### XI. General Operation of a System

A system is provided. The system comprises control circuitry configured to generate control data; and a digital power amplifier including a digital power amplifier cell array comprising a plurality of power amplifier cells, a power amplifier cell from among the plurality of power amplifier cells comprising: a low voltage domain power amplifier cell configured to generate, based on the control data, a low voltage output signal; and a high voltage domain power amplifier cell configured to generate, based on the control data, a high voltage output signal. The control data facilitates a separate activation of the low voltage domain power amplifier cell and the high voltage domain power amplifier cell to selectively adjust a transmit power level of the digital power amplifier. In addition or in alternative to and in any combination with the optional features previously explained in this paragraph, the control circuitry is configured to generate the control data to facilitate, for a transmit power level in accordance with a first communication protocol, the low voltage domain power amplifier cell to generate the low voltage output signal based at least in part on the high voltage domain power amplifier cell being in a high-impedance state. In addition or in alternative to and in any combination with the optional features previously explained in this paragraph, the control circuitry is configured to generate the control data to facilitate, for a data transmission power level in accordance with a second communication protocol that is associated with a higher power transmission level than the first communication protocol, the low voltage domain power amplifier cell to generate the low voltage output signal based at least in part on the high voltage domain power amplifier cell generating the high voltage output signal. In addition or in alternative to and in any combination with the optional features previously explained in this paragraph, the low voltage domain power amplifier cell comprises a low voltage output stage coupled to a set of low voltage resonance capacitors with a first capacitor value, and the high voltage domain power amplifier cell comprises a high voltage output stage coupled to a set of high voltage resonance capacitors with a second capacitor value. In addition or in alternative to and in any combination with the optional features previously explained in this paragraph, the system further comprises a combiner coupled to the low voltage domain power amplifier cell and the high voltage domain power amplifier cell, the combiner comprising: a first primary branch configured to be loaded with an output capacitance of the low voltage domain power amplifier cell; a second primary branch configured to be loaded with an output capacitance of the high voltage domain power amplifier cell; and a secondary branch that couples the first primary branch and the second primary branch to an output of a digital power amplifier. In addition or in alternative to and in any combination with the optional features previously explained in this paragraph, the high voltage domain power amplifier cell further comprises a differential level shifter configured to receive a low voltage input signal based on the control data, and to generate a high voltage differential signal comprising a pair of high voltage signals with an amplitude that substantially matches an amplitude of the low voltage input signal. In addition or in alternative to and in any combination with the optional features previously explained in this paragraph, the high voltage domain power amplifier cell further comprises an output stage that includes a stacked floating gate feedback arrangement of transistors. In addition or in alternative to and in any combination with the optional features previously explained in this paragraph, the low voltage domain power amplifier cell further comprises an output stage that includes a single pair of transistor drivers.

### XII. General Operation of a Method

A method is provided. The method comprises generating control data; providing a digital power amplifier cell array comprising a plurality of power amplifier cells, a power amplifier cell from among the plurality of power amplifier cells comprising: a low voltage domain power amplifier cell configured to generate, based on the control data, a low voltage output signal; and a high voltage domain power amplifier cell configured to generate, based on the control data, a high voltage output signal; and setting a transmit power level by separately activating, based upon the control data, the low voltage domain power amplifier cell and the high voltage domain power amplifier cell; and transmitting a wireless signal in accordance with the transmit power level. In addition or in alternative to and in any combination with the optional features previously explained in this paragraph, the method further comprises causing the high voltage domain power amplifier cell to be placed into a high-impedance state; and transmitting the wireless signal via the low voltage domain power amplifier cell based upon the low voltage output signal in accordance with a first power communication protocol based at least in part on the high voltage domain power amplifier cell being in the high-impedance state. In addition or in alternative to and in any combination with the optional features previously explained in this paragraph, the method further comprises activating the low voltage domain power amplifier cell and the high voltage domain power amplifier cell; and transmitting the wireless signal based on both the low voltage output signal and the high voltage output signal in accordance with a second power communication protocol that is associated with a higher power transmission level than the first power communication protocol. In addition or in alternative to and in any combination with the optional features previously explained in this paragraph, the method further comprises providing a high voltage output stage for the high voltage domain power amplifier cell that includes a stacked floating gate feedback arrangement of transistors; and providing a low voltage output stage for the low voltage domain power amplifier cell that includes a single pair of transistor drivers.

### EXAMPLES

The following examples pertain to various techniques of the present disclosure.
An example (e.g. example 1), is directed to an apparatus comprising: a data interface configured to receive control data; and a digital power amplifier cell array comprising a plurality of power amplifier cells, a power amplifier cell from among the plurality of power amplifier cells comprising: a low voltage domain power amplifier cell configured to generate, based on the control data, a low voltage output signal; and a high voltage domain power amplifier cell configured to generate, based on the control data, a high voltage output signal, wherein the control data facilitates a separate activation of the low voltage domain power amplifier cell and the high voltage domain power amplifier cell to selectively adjust a transmit power level.
Another example (e.g. example 2), relates to a previously-described example (e.g. example 1), wherein the control data facilitates, for a transmit power level in accordance with a first communication protocol, the low voltage domain power amplifier cell generating the low voltage output signal based at least in part on the high voltage domain power amplifier cell being in a high-impedance state.
Another example (e.g. example 3) relates to a previously-described example (e.g. one or more of examples 1-2), wherein the control data facilitates, for a transmit power level in accordance with a second communication protocol that is associated with a higher power transmission level than the first communication protocol, the low voltage domain power amplifier cell generating the low voltage output signal based at least in part on the high voltage domain power amplifier cell generating the high voltage output signal.
Another example (e.g. example 4) relates to a previously-described example (e.g. one or more of examples 1-3), wherein the low voltage domain power amplifier cell comprises a low voltage output stage coupled to a set of low voltage resonance capacitors with a first capacitor value, and wherein the high voltage domain power amplifier cell comprises a high voltage output stage coupled to a set of high voltage resonance capacitors with a second capacitor value.
Another example (e.g. example 5) relates to a previously-described example (e.g. one or more of examples 1-4), further comprising: a combiner coupled to the low voltage domain power amplifier cell and the high voltage domain power amplifier cell, the combiner comprising: a first primary branch configured to be loaded with an output capacitance of the low voltage domain power amplifier cell; a second primary branch configured to be loaded with an output capacitance of the high voltage domain power amplifier cell; and a secondary branch that couples the first primary branch and the second primary branch to an output of a digital power amplifier.
Another example (e.g. example 6) relates to a previously-described example (e.g. one or more of examples 1-5), wherein the high voltage domain power amplifier cell further comprises a differential level shifter configured to receive a low voltage input signal based on the control data, and to generate a high voltage differential signal comprising a pair of high voltage signals with an amplitude that substantially matches an amplitude of the low voltage input signal.
Another example (e.g. example 7) relates to a previously-described example (e.g. one or more of examples 1-6), wherein the high voltage domain power amplifier cell further comprises an output stage that includes a stacked floating gate feedback arrangement of transistors.
Another example (e.g. example 8) relates to a previously-described example (e.g. one or more of examples 1-7), wherein the low voltage domain power amplifier cell further comprises an output stage that includes a single pair of transistor drivers.
An example (e.g. example 9), is directed to a system, comprising: control circuitry configured to generate control data; and a digital power amplifier including a digital power amplifier cell array comprising a plurality of power amplifier cells, a power amplifier cell from among the plurality of power amplifier cells comprising: a low voltage domain power amplifier cell configured to generate, based on the control data, a low voltage output signal; and a high voltage domain power amplifier cell configured to generate, based on the control data, a high voltage output signal, wherein the control data facilitates a separate activation of the low voltage domain power amplifier cell and the high voltage domain power amplifier cell to selectively adjust a transmit power level of the digital power amplifier.
Another example (e.g. example 10), relates to a previously-described example (e.g. example 9), wherein the control circuitry is configured to generate the control data to facilitate, for a transmit power level in accordance with a first communication protocol, the low voltage domain power amplifier cell to generate the low voltage output signal based at least in part on the high voltage domain power amplifier cell being in a high-impedance state.
Another example (e.g. example 11) relates to a previously-described example (e.g. one or more of examples 9-10), wherein the control circuitry is configured to generate the control data to facilitate, for a data transmission power level in accordance with a second communication protocol that is associated with a higher power transmission level than the first communication protocol, the low voltage domain power amplifier cell to generate the low voltage output signal based at least in part on the high voltage domain power amplifier cell generating the high voltage output signal.
Another example (e.g. example 12) relates to a previously-described example (e.g. one or more of examples 9-11), wherein the low voltage domain power amplifier cell comprises a low voltage output stage coupled to a set of low voltage resonance capacitors with a first capacitor value, and wherein the high voltage domain power amplifier cell comprises a high voltage output stage coupled to a set of high voltage resonance capacitors with a second capacitor value.
Another example (e.g. example 13) relates to a previously-described example (e.g. one or more of examples 9-12), further comprising: a combiner coupled to the low voltage domain power amplifier cell and the high voltage domain power amplifier cell, the combiner comprising: a first primary branch configured to be loaded with an output capacitance of the low voltage domain power amplifier cell; a second primary branch configured to be loaded with an output capacitance of the high voltage domain power amplifier cell; and a secondary branch that couples the first primary branch and the second primary branch to an output of a digital power amplifier.
Another example (e.g. example 14) relates to a previously-described example (e.g. one or more of examples 9-13), wherein the high voltage domain power amplifier cell further comprises a differential level shifter configured to receive a low voltage input signal based on the control data, and to generate a high voltage differential signal comprising a pair of high voltage signals with an amplitude that substantially matches an amplitude of the low voltage input signal.
Another example (e.g. example 15) relates to a previously-described example (e.g. one or more of examples 9-14), wherein the high voltage domain power amplifier cell further comprises an output stage that includes a stacked floating gate feedback arrangement of transistors.
Another example (e.g. example 16) relates to a previously-described example (e.g. one or more of examples 9-15), wherein the low voltage domain power amplifier cell further comprises an output stage that includes a single pair of transistor drivers.
An example (e.g. example 17), is directed to a method, comprising: generating control data; providing a digital power amplifier cell array comprising a plurality of power amplifier cells, a power amplifier cell from among the plurality of power amplifier cells comprising: a low voltage domain power amplifier cell configured to generate, based on the control data, a low voltage output signal; and a high voltage domain power amplifier cell configured to generate, based on the control data, a high voltage output signal; and setting a transmit power level by separately activating, based upon the control data, the low voltage domain power amplifier cell and the high voltage domain power amplifier cell; and transmitting a wireless signal in accordance with the transmit power level.
Another example (e.g. example 18), relates to a previously-described example (e.g. example 17), further comprising: causing the high voltage domain power amplifier cell to be placed into a high-impedance state; and transmitting the wireless signal via the low voltage domain power amplifier cell based upon the low voltage output signal in accordance with a first power communication protocol based at least in part on the high voltage domain power amplifier cell being in the high-impedance state.
Another example (e.g. example 19) relates to a previously-described example (e.g. one or more of examples 17-18), further comprising: activating the low voltage domain power amplifier cell and the high voltage domain power amplifier cell; and transmitting the wireless signal based on both the low voltage output signal and the high voltage output signal in accordance with a second power communication protocol that is associated with a higher power transmission level than the first power communication protocol.
Another example (e.g. example 20) relates to a previously-described example (e.g. one or more of examples 17-19), further comprising: providing a high voltage output stage for the high voltage domain power amplifier cell that includes a stacked floating gate feedback arrangement of transistors; and providing a low voltage output stage for the low voltage domain power amplifier cell that includes a single pair of transistor drivers.
An example (e.g. example 21), is directed to an apparatus, comprising: a data interface means for receiving control data; and a digital power amplifier cell array comprising a plurality of power amplifier cells, a power amplifier cell from among the plurality of power amplifier cells comprising: a low voltage domain power amplifier cell means for generating, based on the control data, a low voltage output signal; and a high voltage domain power amplifier cell means for generating, based on the control data, a high voltage output signal, wherein the control data facilitates a separate activation of the low voltage domain power amplifier cell means and the high voltage domain power amplifier cell means to selectively adjust a transmit power level.
Another example (e.g. example 22), relates to a previously-described example (e.g. example 21), wherein the control data facilitates, for a transmit power level in accordance with a first communication protocol, the low voltage domain power amplifier cell means generating the low voltage output signal based at least in part on the high voltage domain power amplifier cell means being in a high-impedance state.
Another example (e.g. example 23) relates to a previously-described example (e.g. one or more of examples 21-22), wherein the control data facilitates, for a transmit power level in accordance with a second communication protocol that is associated with a higher power transmission level than the first communication protocol, the low voltage domain power amplifier cell means generating the low voltage output signal based at least in part on the high voltage domain power amplifier cell means generating the high voltage output signal.
Another example (e.g. example 24) relates to a previously-described example (e.g. one or more of examples 21-23), wherein the low voltage domain power amplifier cell means comprises a low voltage output stage coupled to a set of low voltage resonance capacitors with a first capacitor value, and wherein the high voltage domain power amplifier cell means comprises a high voltage output stage coupled to a set of high voltage resonance capacitors with a second capacitor value.
Another example (e.g. example 25) relates to a previously-described example (e.g. one or more of examples 21-24), further comprising: a combiner coupled to the low voltage domain power amplifier cell means and the high voltage domain power amplifier cell means, the combiner comprising: a first primary branch configured to be loaded with an output capacitance of the low voltage domain power amplifier cell; a second primary branch configured to be loaded with an output capacitance of the high voltage domain power amplifier cell; and a secondary branch that couples the first primary branch and the second primary branch to an output of a digital power amplifier.
Another example (e.g. example 26) relates to a previously-described example (e.g. one or more of examples 21-25), wherein the high voltage domain power amplifier cell means further comprises a differential level shifter configured to receive a low voltage input signal based on the control data, and to generate a high voltage differential signal comprising a pair of high voltage signals with an amplitude that substantially matches an amplitude of the low voltage input signal.
Another example (e.g. example 27) relates to a previously-described example (e.g. one or more of examples 21-26), wherein the high voltage domain power amplifier cell means further comprises an output stage that includes a stacked floating gate feedback arrangement of transistors.
Another example (e.g. example 28) relates to a previously-described example (e.g. one or more of examples 21-27), wherein the low voltage domain power amplifier cell means further comprises an output stage that includes a single pair of transistor drivers.
An example (e.g. example 29), is directed to a system, comprising: control circuitry means for generating control data; and a digital power amplifier including a digital power amplifier cell array comprising a plurality of power amplifier cells, a power amplifier cell from among the plurality of power amplifier cells comprising: a low voltage domain power amplifier cell means for generating, based on the control data, a low voltage output signal; and a high voltage domain power amplifier cell means for generating, based on the control data, a high voltage output signal, wherein the control data facilitates a separate activation of the low voltage domain power amplifier cell means and the high voltage domain power amplifier cell means to selectively adjust a transmit power level of the digital power amplifier.
Another example (e.g. example 30), relates to a previously-described example (e.g. example 29), wherein the control circuitry means generates the control data to facilitate, for a transmit power level in accordance with a first communication protocol, the low voltage domain power amplifier cell means generating the low voltage output signal based at least in part on the high voltage domain power amplifier cell means being in a high-impedance state.
Another example (e.g. example 31) relates to a previously-described example (e.g. one or more of examples 29-30), wherein the control circuitry means generates the control data to facilitate, for a data transmission power level in accordance with a second communication protocol that is associated with a higher power transmission level than the first communication protocol, the low voltage domain power amplifier cell means generating the low voltage output signal based at least in part on the high voltage domain power amplifier cell means generating the high voltage output signal.
Another example (e.g. example 32) relates to a previously-described example (e.g. one or more of examples 29-31), wherein the low voltage domain power amplifier cell means comprises a low voltage output stage coupled to a set of low voltage resonance capacitors with a first capacitor value, and wherein the high voltage domain power amplifier cell means comprises a high voltage output stage coupled to a set of high voltage resonance capacitors with a second capacitor value.
Another example (e.g. example 33) relates to a previously-described example (e.g. one or more of examples 29-32), further comprising: a combiner coupled to the low voltage domain power amplifier cell and the high voltage domain power amplifier cell, the combiner comprising: a first primary branch configured to be loaded with an output capacitance of the low voltage domain power amplifier cell; a second primary branch configured to be loaded with an output capacitance of the high voltage domain power amplifier cell; and a secondary branch that couples the first primary branch and the second primary branch to an output of a digital power amplifier.
Another example (e.g. example 34) relates to a previously-described example (e.g. one or more of examples 29-33), wherein the high voltage domain power amplifier cell means further comprises a differential level shifter configured to receive a low voltage input signal based on the control data, and to generate a high voltage differential signal comprising a pair of high voltage signals with an amplitude that substantially matches an amplitude of the low voltage input signal.
Another example (e.g. example 35) relates to a previously-described example (e.g. one or more of examples 29-34), wherein the high voltage domain power amplifier cell means further comprises an output stage that includes a stacked floating gate feedback arrangement of transistors.
Another example (e.g. example 36) relates to a previously-described example (e.g. one or more of examples 29-35), wherein the low voltage domain power amplifier cell means further comprises an output stage that includes a single pair of transistor drivers.
An example (e.g. example 37), is directed to a method, comprising: generating control data; providing a digital power amplifier cell array comprising a plurality of power amplifier cells, a power amplifier cell from among the plurality of power amplifier cells comprising: a low voltage domain power amplifier cell means for generating, based on the control data, a low voltage output signal; and a high voltage domain power amplifier cell means for generating, based on the control data, a high voltage output signal; and setting a transmit power level by separately activating, based upon the control data, the low voltage domain power amplifier cell means and the high voltage domain power amplifier cell means; and transmitting a wireless signal in accordance with the transmit power level.
Another example (e.g. example 38), relates to a previously-described example (e.g. example 37), further comprising: causing the high voltage domain power amplifier cell means to be placed into a high-impedance state; and transmitting the wireless signal via the low voltage domain power amplifier cell means based upon the low voltage output signal in accordance with a first power communication protocol based at least in part on the high voltage domain power amplifier cell means being in the high-impedance state.
Another example (e.g. example 39) relates to a previously-described example (e.g. one or more of examples 37-38), further comprising: activating the low voltage domain power amplifier cell means and the high voltage domain power amplifier cell means; and transmitting the wireless signal based on both the low voltage output signal and the high voltage output signal in accordance with a second power communication protocol that is associated with a higher power transmission level than the first power communication protocol.
Another example (e.g. example 40) relates to a previously-described example (e.g. one or more of examples 37-39), further comprising: providing a high voltage output stage for the high voltage domain power amplifier cell means that includes a stacked floating gate feedback arrangement of transistors; and providing a low voltage output stage for the low voltage domain power amplifier cell means that includes a single pair of transistor drivers.

An apparatus as shown and described.

A method as shown and described.

### CONCLUSION

The aforementioned description of the specific aspects will so fully reveal the general nature of the disclosure that others can, by applying knowledge within the skill of the art, readily modify and/or adapt for various applications such specific aspects, without undue experimentation, and without departing from the general concept of the present disclosure. Therefore, such adaptations and modifications are intended to be within the meaning and range of equivalents of the disclosed aspects, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

References in the specification to “one aspect,” “an aspect,” “an exemplary aspect,” etc., indicate that the aspect described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is submitted that it is within the knowledge of one skilled in the art to affect such feature, structure, or characteristic in connection with other aspects whether or not explicitly described.

The exemplary aspects described herein are provided for illustrative purposes, and are not limiting. Other exemplary aspects are possible, and modifications may be made to the exemplary aspects. Therefore, the specification is not meant to limit the disclosure. Rather, the scope of the disclosure is defined only in accordance with the following claims and their equivalents.

Aspects may be implemented in hardware (e.g., circuits), firmware, software, or any combination thereof. Aspects may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

For the purposes of this discussion, the term “processing circuitry” or “processor circuitry” shall be understood to be circuit(s), processor(s), logic, or a combination thereof. For example, a circuit can include an analog circuit, a digital circuit, state machine logic, other structural electronic hardware, or a combination thereof. A processor can include a microprocessor, a digital signal processor (DSP), or other hardware processor. The processor can be “hard-coded” with instructions to perform corresponding function(s) according to aspects described herein. Alternatively, the processor can access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary aspects described herein, processing circuitry can include memory that stores data and/or instructions. The memory can be any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

What is claimed is:

1. An apparatus, comprising:
a data interface configured to receive control data; and
a digital power amplifier cell array comprising a plurality of power amplifier cells, a power amplifier cell from among the plurality of power amplifier cells comprising:
a low voltage domain power amplifier cell configured to generate, based on the control data, a low voltage output signal; and
a high voltage domain power amplifier cell configured to generate, based on the control data, a high voltage output signal,
wherein the control data facilitates a separate activation of the low voltage domain power amplifier cell and the high voltage domain power amplifier cell to selectively adjust a transmit power level.

2. The apparatus of claim 1, wherein the control data facilitates, for a transmit power level in accordance with a first communication protocol, the low voltage domain power amplifier cell generating the low voltage output signal based at least in part on the high voltage domain power amplifier cell being in a high-impedance state.

3. The apparatus of claim 2, wherein the control data facilitates, for a transmit power level in accordance with a second communication protocol that is associated with a higher power transmission level than the first communication protocol, the low voltage domain power amplifier cell generating the low voltage output signal based at least in part on the high voltage domain power amplifier cell generating the high voltage output signal.

4. The apparatus of claim 1, wherein the low voltage domain power amplifier cell comprises a low voltage output stage coupled to a set of low voltage resonance capacitors with a first capacitor value, and
wherein the high voltage domain power amplifier cell comprises a high voltage output stage coupled to a set of high voltage resonance capacitors with a second capacitor value.

5. The apparatus of claim 1, further comprising:
a combiner coupled to the low voltage domain power amplifier cell and the high voltage domain power amplifier cell, the combiner comprising:
a first primary branch configured to be loaded with an output capacitance of the low voltage domain power amplifier cell;
a second primary branch configured to be loaded with an output capacitance of the high voltage domain power amplifier cell; and
a secondary branch that couples the first primary branch and the second primary branch to an output of a digital power amplifier.

6. The apparatus of claim 1, wherein the high voltage domain power amplifier cell further comprises a differential level shifter configured to receive a low voltage input signal based on the control data, and to generate a high voltage differential signal comprising a pair of high voltage signals with an amplitude that substantially matches an amplitude of the low voltage input signal.

7. The apparatus of claim 1, wherein the high voltage domain power amplifier cell further comprises an output stage that includes a stacked floating gate feedback arrangement of transistors.

8. The apparatus of claim 1, wherein the low voltage domain power amplifier cell further comprises an output stage that includes a single pair of transistor drivers.

9. A system, comprising:
control circuitry configured to generate control data; and
a digital power amplifier including a digital power amplifier cell array comprising a plurality of power amplifier cells, a power amplifier cell from among the plurality of power amplifier cells comprising:
a low voltage domain power amplifier cell configured to generate, based on the control data, a low voltage output signal; and
a high voltage domain power amplifier cell configured to generate, based on the control data, a high voltage output signal,
wherein the control data facilitates a separate activation of the low voltage domain power amplifier cell and the high voltage domain power amplifier cell to selectively adjust a transmit power level of the digital power amplifier.

10. The system of claim 9, wherein the control circuitry is configured to generate the control data to facilitate, for a transmit power level in accordance with a first communication protocol, the low voltage domain power amplifier cell to generate the low voltage output signal based at least in part on the high voltage domain power amplifier cell being in a high-impedance state.

11. The system of claim 10, wherein the control circuitry is configured to generate the control data to facilitate, for a data transmission power level in accordance with a second communication protocol that is associated with a higher power transmission level than the first communication protocol, the low voltage domain power amplifier cell to generate the low voltage output signal based at least in part on the high voltage domain power amplifier cell generating the high voltage output signal.

12. The system of claim 9, wherein the low voltage domain power amplifier cell comprises a low voltage output stage coupled to a set of low voltage resonance capacitors with a first capacitor value, and
wherein the high voltage domain power amplifier cell comprises a high voltage output stage coupled to a set of high voltage resonance capacitors with a second capacitor value.

13. The system of claim 9, further comprising:
a combiner coupled to the low voltage domain power amplifier cell and the high voltage domain power amplifier cell, the combiner comprising:
a first primary branch configured to be loaded with an output capacitance of the low voltage domain power amplifier cell;
a second primary branch configured to be loaded with an output capacitance of the high voltage domain power amplifier cell; and
a secondary branch that couples the first primary branch and the second primary branch to an output of a digital power amplifier.

14. The system of claim 9, wherein the high voltage domain power amplifier cell further comprises a differential level shifter configured to receive a low voltage input signal based on the control data, and to generate a high voltage differential signal comprising a pair of high voltage signals with an amplitude that substantially matches an amplitude of the low voltage input signal.

15. The system of claim 9, wherein the high voltage domain power amplifier cell further comprises an output stage that includes a stacked floating gate feedback arrangement of transistors.

16. The system of claim 9, wherein the low voltage domain power amplifier cell further comprises an output stage that includes a single pair of transistor drivers.

17. A method, comprising:
generating control data;
providing a digital power amplifier cell array comprising a plurality of power amplifier cells, a power amplifier cell from among the plurality of power amplifier cells comprising:
a low voltage domain power amplifier cell configured to generate, based on the control data, a low voltage output signal; and
a high voltage domain power amplifier cell configured to generate, based on the control data, a high voltage output signal; and
setting a transmit power level by separately activating, based upon the control data, the low voltage domain power amplifier cell and the high voltage domain power amplifier cell; and
transmitting a wireless signal in accordance with the transmit power level.

18. The method of claim 17, further comprising:
causing the high voltage domain power amplifier cell to be placed into a high-impedance state; and
transmitting the wireless signal via the low voltage domain power amplifier cell based upon the low voltage output signal in accordance with a first power communication protocol based at least in part on the high voltage domain power amplifier cell being in the high-impedance state.

19. The method of claim 17, further comprising:
activating the low voltage domain power amplifier cell and the high voltage domain power amplifier cell; and
transmitting the wireless signal based on both the low voltage output signal and the high voltage output signal in accordance with a second power communication protocol that is associated with a higher power transmission level than the first power communication protocol.

20. The method of claim 17, further comprising:
providing a high voltage output stage for the high voltage domain power amplifier cell that includes a stacked floating gate feedback arrangement of transistors; and
providing a low voltage output stage for the low voltage domain power amplifier cell that includes a single pair of transistor drivers.
